(19) United States
(12) Patent Application Publication
(10) Pub. No.: US 2024/0336798 A1
(43) Pub. Date: Oct. 10, 2024

(54) PEROVSKITES COMPOSITIONS, METHODS OF PRODUCING, METHODS OF USE, AND MATERIALS THEREOF

(71) Applicant: ARIZONA BOARD OF REGENTS ON BEHALF OF ARIZONA STATE UNIVERSITY, Scottsdale, AZ (US)

(72) Inventors: Nicholas Rolston, Phoenix, AZ (US); Carsen Cartledge, Paradise Valley, AZ (US); Muneeza Ahmad, Tempe, AZ (US)

(21) Appl. No.: 18/630,796

(22) Filed: Apr. 9, 2024

Related U.S. Application Data
(60) Provisional application No. 63/458,395, filed on Apr. 10, 2023.

(51) Int. Cl. C09D 11/52; C09D 11/037; C09D 11/14; H10K 30/50; H10K 71/12; H10K 71/40

(52) U.S. Cl. CPC C09D 11/52; C09D 11/037; C09D 11/14; H10K 30/50; H10K 71/12; H10K 71/40

(57) ABSTRACT

The invention encompasses perovskite additives, compositions, methods of use, and materials thereof.

This application claims priority to U.S. Provisional Application No. 63/458,395, filed on Apr. 10, 2023, the entire contents of which are incorporated herein in its entirety.

All patents, patent applications and publications cited herein are hereby incorporated by reference in their entirety. The disclosures of these publications in their entireties are hereby incorporated by reference into this application in order to more fully describe the state of the art as known to those skilled therein as of the date of the invention described and claimed herein.

This patent disclosure contains material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF THE INVENTION

The present invention relates to perovskite additives, compositions, methods of use, and materials thereof.

### BACKGROUND OF THE INVENTION

Perovskite materials hold the potential for making high-efficiency, low-cost solar devices through solution processing of Earth abundant materials. Research utilizes spin coating as a means of reliable application, but this method lacks the scalability demanded in industry.

### SUMMARY OF THE INVENTION

Aspects of the invention are drawn towards a method of producing a quench-free perovskite material in ambient conditions, the method comprising: mixing a perovskite precursor with an organic solvent, thereby producing a perovskite precursor solution; incorporating a polymer additive into the perovskite precursor solution, thereby producing a perovskite-polymer ink; depositing the perovskite-polymer ink on a substrate; and flame annealing the perovskite-polymer ink on the substrate, thereby producing a quench-free perovskite material in ambient conditions. In embodiments, the perovskite precursor comprises CH₃NH₃PbI₃. In embodiments, the polymer additive comprises gellan gum. In embodiments, the polymer additive comprises a polymer of the following structure:

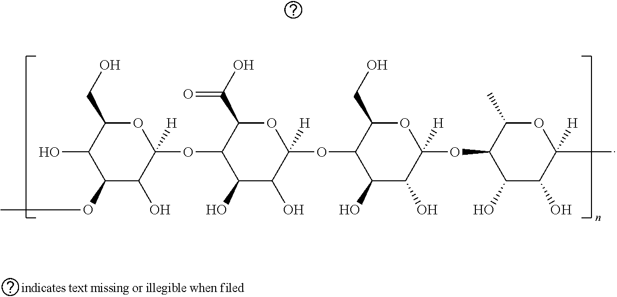

In embodiments, the polymer additive is present in about 0.01 wt. % to about 2.29 wt. % of the perovskite precursors. In embodiments, the polymer additive is present in about 0.18 wt. % to about 0.56 wt. % of the perovskite precursors. In embodiments, depositing comprises blade coating, bar coating, slot die coating, spray coating, inkjet printing, and gravure printing. In embodiments, the flame annealing comprises an exposure to flame discharge at speeds comprising about 0.1 m/min to about 1000 m/min. In embodiments, flame annealing comprises flame exposure at a distance of about 0.1 cm to about 10 cm. In embodiments, the method does not require a quenching step. In embodiments, the perovskite material has improved fracture energy compared to a solution-processed material. For example, the fracture energy is greater than about 6.0 J/m². For example, the fracture energy is about 6.6+/−2.5 J/m² to about 10.9+/−2.3 J/m².

In embodiments, the method further comprises tuning the morphology of the perovskite material by adjusting the concentration of the polymer additive to reduce the amount of nucleation. In embodiments, the morphology comprises domains greater than about 1 mm. In embodiments, the perovskite material has a root mean square roughness of about 1 nm to about 50 nm. In embodiments, the perovskite material has a carrier lifetime of greater than about 1 μs. In embodiments, the perovskite has increased resistance against heat and humidity.

Aspects of the invention are drawn towards a perovskite material produced by the methods described here. For example, the material is a perovskite solar cell. Other objects and advantages of this invention will become readily apparent from the ensuing description.

### BRIEF DESCRIPTION OF THE FIGURES

The patent or application file contains at least one drawing executed in color. Copies of this patent or patent application publication with color drawing(s) will be provided by the Office upon request and payment of necessary fee.

FIG. 1 shows rheological data indicating the effects of different concentrations of gellan gum to MAPI ink with respect to honey, water, and the pure DMSO.

FIG. 2 shows non-limiting, exemplary data. Panel (a) shows a modified LaMer curve depicting supersaturation rates as a function of precursor concentration in wet films undergoing drying respective to processing time. The red curve represents a case of rapid supersaturation with burst nucleation and little time for crystal growth which is characteristic of antisolvent induced crystallization, the green line represents the introduction of an optimized amount of GG whereby burst nucleation occurs at a lower degree of supersaturation thus allowing more time for crystal growth which yields larger domains, and the grey line represents a case where fewer stable nucleates form leading to extended crystal growth on available sites resulting in a void-filled dendritic structure (Panel b) AFM image of fine grained MAPI spin coated with an antisolvent in a nitrogen glovebox. (Panels c-f) AFM images of ambient blade coated samples with increasing amounts of GG from unmodified to 2.29% showing the change in morphology from variable dendrites to homogeneous domains as suggested by the LaMer curve. (Panels g-k) Corresponding transmission optical microscopy images of (Panels b-f) further demonstrating the uniformity and changes in morphology enabled by GG. All transmission images were captured with the same lighting conditions.

FIG. 3 shows non-limiting, exemplary data. Panels (a-c) Illuminated lock-in thermal topography images of 0%, 0.18%, and 0.56% GG with scale bar indicating minimum temperature as dark spot and maximum temperature as bright spot, all the images have a common scale of 4.6 μm per pixel (d) I-V response of the blade coated thin films on ITO glass with 0% and 0.18% GG samples showing poor response versus 0.56% GG.

FIG. 4 shows (Panels a-c) XRD spectrums of ambient blade coated MAPI with 0%, 0.18%, and 0.56% GG after 0, 3, and 12 total hours of humidity aging at 85% RH with accompanying color-coded macroscale camera photographs after each step in the aging process. Both the MAPI and 0.18% GG films near complete loss of the black photoreactive phase both visually and as evidenced by the loss of characteristic perovskite peaks accompanied by a dramatic increase in PbI₂ peak intensities after 12 hours while 0.56% GG retains its perovskite peaks with only slight PbI₂ peak intensification. Each XRD spectrum includes labeled dominate MAPI and PbI₂ peaks denoted by miller indices or a star, respectively (Panels d-f) corresponding PL spectrums confirming near complete degradation of optoelectronic properties for MAPI and 0.18% GG films while 0.56% GG retains a significant portion of its PL, indicating enhanced stability.

FIG. 5 shows (panels a-c) XRD spectrums of ambient blade coated MAPI with 0%, 0.18%, and 0.56% GG after 0, 3, and 12 total hours of heat exposure at 85° C. with accompanying color-coded macroscale camera photographs after each step in the aging process. Both the MAPI and 0.18% GG films feature a stronger increase in PbI₂ peak intensities after 12 hours than 0.56% GG, and the improved film quality is further supported through the inset transmission photographs. Each XRD spectrum includes labeled dominate MAPI and PbI₂ peaks denoted by miller indices or a star, respectively, and FIG. 8 provides these spectrums plotted on a wider 20 axis (panels d-f) Corresponding PL spectrums confirming the ability of 0.56% GG to slow degradation of optoelectronic properties compared to 0% and 0.18% GG films, indicating enhanced stability.

FIG. 6 shows (panel a) Fracture energies collected from double cantilever beam testing for spin coated 0% GG in an inert environment and ambient blade coated 0.18% and optimized 0.56% GG given with respect to the range of fracture energies for crystalline silicon cells, >10 J/m^{2 [28}] (panel b) schematic of a double cantilever beam testing sample demonstrating fracture occurring through the PVSK.

FIG. 7 shows (panels a-c) Illuminated lock-in illumination amplitude images with scale bar indicating low amplitude to high amplitude of captured thermal emission, (panels d-f) Illumination phase images with scale bar indicating captured light being in-phase to out-of-phase of the light pulse. (panels a,d) 0% GG, (b,c) 0.18% GG, (c,f) 0.56% GG. All the images have a common scale of 4.6 μm per pixel.

FIG. 8 shows XRD spectrum of PVSK films before and after being exposed to 85° C. for 12 hours. This is the same data that were previously plotted in FIG. 5 (panels a-c) now on an extended 20 axis for 0%, 0.18%, and 0.56% GG samples showing the change in orientational dominance induced by GG and heat aging which likely corresponds to stress relaxation in the film.

FIG. 9 shows 2D (out of plane Qx-Qz where Qy is the beam direction) adjusted GIWAXS spectrums collected on as blade coated samples, (panels a-b) 0% GG, (panels c-d) 0.18% GG, and (panels e-f) 0.56% GG, at different penetration depths demonstrating stronger crystallographic texturing with increasing GG concentrations whereby the films transition from having randomly oriented 3D bulk crystal banding to a partially to highly oriented 3D bulk crystal structure in the 0.18% GG and optimized 0.56% GG films. Band distortion and outward smearing is thought to be due to the instrumentation and stage set-up rather than a crystallographic feature.

FIG. 10 shows non-limiting, exemplary atomic force microscopy and transmission images of the results of spin coating and blade coating.

FIG. 11 shows non-limiting, exemplary glow discharge optical emission spectroscopy (GDOES) spectra.

FIG. 12 shows non-limiting, exemplary glow discharge optical emission spectroscopy (GDOES) spectra.

FIG. 13 shows a non-limiting, exemplary photoluminescence spectroscopy spectrum.

FIG. 14 shows a non-limiting, exemplary photograph of indium tin oxide coated polyethylene terephthalate (ITO-PET) blade coated samples. All 15 ul, blade at 250 μm, preheat ITO PET at 40° C., anneal 30 min at 100° C.

FIG. 15 shows non-limiting, exemplary photoluminescence spectroscopy spectra.

FIG. 16 shows a non-limiting, exemplary schematic and XRD spectra.

FIG. 17 shows a non-limiting, exemplary LaMer curve and AFM images.

FIG. 18 shows non-limiting, exemplary photoluminescence spectroscopy spectra.

### DETAILED DESCRIPTION OF THE INVENTION

Aspects described herein provide perovskite additives, compositions, methods of use, and materials thereof.

Detailed descriptions of one or more embodiments are provided herein. It is to be understood, however, that the present invention can be embodied in various forms. Therefore, specific details disclosed herein are not to be interpreted as limiting, but rather as a basis for the claims and as a representative basis for teaching one skilled in the art to employ the present invention in any appropriate manner.

The singular forms “a”, “an” and “the” include plural reference unless the context clearly dictates otherwise. The use of the word “a” or “an” when used in conjunction with the term “comprising” in the claims and/or the specification can mean “one,” but it is also consistent with the meaning of “one or more,” “at least one,” and “one or more than one.”

Wherever any of the phrases “for example,” “such as,” “including” and the like are used herein, the phrase “and without limitation” is understood to follow unless explicitly stated otherwise. Similarly, “an example,” “exemplary” and the like are understood to be nonlimiting.

The term “substantially” allows for deviations from the descriptor that do not negatively impact the intended purpose. Descriptive terms are understood to be modified by the term “substantially” even if the word “substantially” is not explicitly recited.

The terms “comprising” and “including” and “having” and “involving” (and similarly “comprises”, “includes,” “has,” and “involves”) and the like are used interchangeably and have the same meaning. Specifically, each of the terms is defined consistent with the common United States patent law definition of “comprising” and is therefore interpreted to be an open term meaning “at least the following,” and is also interpreted not to exclude additional features, limitations, aspects, etc. Thus, for example, “a process involving steps a, b, and c” means that the process includes at least steps a, b and c. Wherever the terms “a” or “an” are used, “one or more” is understood, unless such interpretation is nonsensical in context.

As used herein, the term “about” can refer to approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower).

As used herein, the term “substantially the same” or “substantially” can refer to variability typical for a particular method is taken into account.

The terms “sufficient” and “effective”, as used interchangeably herein, can refer to an amount (e.g., mass, volume, dosage, concentration, and/or time period) needed to achieve one or more desired result(s).

Before explaining at least one embodiment of the disclosure in detail, it is to be understood that the disclosure is not necessarily limited in its application to the details set forth in the following description or exemplified by the examples. The disclosure is capable of other embodiments or of being practiced or carried out in various ways. Other compositions, compounds, methods, features, and advantages of the present disclosure will be or become apparent to one having ordinary skill in the art upon examination of the following drawings, detailed description, and examples. All such additional compositions, compounds, methods, features, and advantages can be included within this description, and be within the scope of the present disclosure.

Aspects of the invention are drawn towards a method of producing a quench-free perovskite material in ambient conditions, the method comprising: mixing a perovskite precursor with an organic solvent, thereby producing a perovskite precursor solution; incorporating a polymer additive into the perovskite precursor solution, thereby producing a perovskite-polymer ink; depositing the perovskite-polymer ink on a substrate; and processing the perovskite-polymer ink on the substrate, thereby producing a quench-free perovskite material in ambient conditions.

In embodiments, the perovskite-polymer ink composition can vary to tune the chemistry of the perovskite. As used herein, the term “ink” can refer to any fluid, regardless of color, that can be applied to a substrate for manufacturing applications. For example, “ink” can refer to the combination of polymer precursors and solvent.

As used herein, the term “perovskite” can refer to a material or a layer with a three-dimensional crystal structure related to that of CaTIO₃ or CaTiC. The skilled person will appreciate that a perovskite material can be represented by the formula ‘A’‘B’‘X’3, wherein ‘A’ is at least one cation, ‘B’ is at least one cation, and ‘X’ is at least one anion. The cation ‘A’ can be organic, inorganic, or an organic-inorganic cation. When the cation ‘A’ is organic, the organic cation can have the formula (R₁R₂R₃R₄N)n+ or (R₅R₆N═CH—NR₇R₈)n+, where R is hydrogen, unsubstituted or substituted alkyl, or unsubstituted or substituted aryl, and n is equal or superior to one (e.g. ‘CH₃NH₃’+ refers as MA, ‘HC(NH₂)₂’+ refers as FA, ‘C(NH₂)₃’+ refers as GA). When the cation ‘A’ is inorganic, the cation can be selected from the group consisting of Ag⁺, Li⁺, Na⁺, K⁺, Rb⁺, Cs⁺, Be²⁺, Mg²⁺, Ca²⁺, Pb²⁺, Sr²⁺, Ba²⁺, Fe²⁺, Sc³⁺, Y³⁺, and La³⁺. The cation can be used as a single or multiple ion (e.g. (Mg,Fe)SiO₃), YBaCuO₃).

When the cation ‘A’ is organic-inorganic, the cation can be used as a single or multiple ion such as ‘A’=(M1n(R2₁₋ₓR3ₓ) (100−n)), where R is preferably an organic cation as described above and M is preferably an inorganic cation comprised as described above (e.g. FA₁₋ₓGaₓ‘B’‘X’3, Csx(MAₙFA₁₋ₙ) (100−x) ‘B’‘X’3).

The cation ‘B’ can be a metal cation selected from the group consisting of Pb²⁺, Sn²⁺, Gc²⁺, Bi²⁺, Cu²⁺, Au²⁺, Ag²⁺, Sb²⁺, Nb²⁺, Ti²⁺, Mg²⁺, Si²⁺, Ca²⁺, Sr²⁺, Cd²⁺, Ni²⁺, Mn²⁺, Fe²⁺, Zr⁴⁺, Co²⁺, Pd²⁺, Yb²⁺, Eu²⁺, Ce⁴⁺, and Tb⁴⁺. The divalent metal bearing compound can be derived from various salts including but not limited to lead acetate and lead nitrate for instance. The anion ‘X’ can be selected from the group consisting of halide anions comprising Cl—, Br⁻, I⁻, F⁻, or chalcogenide anions comprising O²⁻, S²⁻, Se²⁻, Te²⁻, or polyanions comprising BF⁴⁻, PF⁶⁻, SCN—. The anion can be used as a single or multiple ions such as ‘X’=(R1−xRx), where R is an anion as listed above. Other type of perovskite that can be elaborated: Cuprate perovskite (La₂₋ₓBaₓCuO₄, YBa₂Cu₃O₇, Ba₂MCu₃O₇, where M is a rare earth ion such as Pr, Y, Nd, Sm, Gd, Dy, Ho). Metal perovskite can be produced based on a RT3M structure, where R is a rare-earth ion, T is a transition metal ion (Pd, Rh, Ru) and M is a light metalloid (e.g. B, C).

In embodiments, perovskite precursor solutions can comprise those known in the art, for example: CH₃NH₃PbX₃, CSx(CH₃(NH₂)₂)₁₋ₓPbX₃, CSx(CH₃NH₃)ₓ(CH₃(NH₂)₂)₁₋ₓ) (100−x)PbX₃, AₓCs_{y}((CH₃NH₃)/(CH₃(NH₂)₂)_{1-z})_{1-y}PbX₃ where A is an alkali metal (Li, Na, K, Rb), suitable for the preparation of photoactive layer; BaTiO₃, PbTiO₃, CaTIO₃, SrTiO₃, PbZrO₃, SrTiO₃, KTaO₃, KNbO₃, NaNbO₃, Pb(Mg_{1/3}Nb_{2/3})O₃, Pb(Zn_{1/3}Nb_{2/3})₃, Pb(Mn₁₃Sb_{2/3})O₃, Pb(Co_{1/3}Nb_{2/3})O₃, Pb(Mn_{1/3}Nb_{2/3})O₃, Pb(Ni₁₃Nb_{2/3})O₃, Pb(Sb_{1/2}Sn_{1/2})O₃, Pb(Co₁₂W_{1/2})O₃, Pb(Mg_{1/2}W_{1/2})O₃, LiNbO₃, LiTaO₃, BiTiO₃, NaTIO₃, NaNbO₃, KNbO₃, for the growth of ferroelectric and piezoelectric material; La₁₋ₓSrₓMnO₃, La₂NiO₄, La₂CoO₄, GdBaCo₂O₅, PrBaCo₂O₅, NdBa₁₋ₓSrₓCoO₂O₅, Ba₁₋ₓSrₓCo_{1-y}Fe_{y}O₃, for the elaboration of fuel cells; BiCr₁₋ₓGaₓO₃, for magnetic materials; NaNbO₃, KNbO₃, LaFcO₃, LaCoₓFc₁₋ₓO₃, La₁₋ₓSrₓCoO₃, LaSrNiO₄, LaₓSrₓ₋₁Fe_{y}Bi_{y-1}O₃, La₂NiO₄, La₂₋ₓSrₓCuO₄, LaSrNi₁₋ₓAlₓO₄, LaMnO₃, LaFcO₃, LaCoO₃, LaTi₁₋ₓCuₓO₃, LiTaO₃, NaTaO₃, KTaO₃, CaTa₂OL₆, SrTa₂O₆, BaTa₂O₆, for catalysis; La-based perovskite-type oxides (La₁₋ₓSrₓCoO₃, Pr₁₋ₓSrₓCoO₃, Sm₁₋ₓSrₓCoO₃, Gd₁₋ₓSrₓCoO₃, Tb₁₋ₓSrₓCoO₃, LaCoO₃, La₁₋ₓSrₓMnO₃, LaCo₁₋ₓNiₓO₃), for electronic conductions.

In embodiments, the perovskite can comprise divalent cations such as propylene diammonium (e.g., Dion-Jacobson perovskite) in addition to the monovalent cations (e.g., Ruddledsen-Popper) (scc, e.g., R. Liu, X. Hu, M. Xu, H. Ren, H. Yu, ChemSusChem 2023, 16, e202300736). In embodiments, the disclosure can comprise cations selected from the group consisting of formamidinium, cesium, rubidium, sodium, potassium, dimethylammonium, butylammonium, propylene diammonium, benzylammonium, and phenethylammonium. The skilled person will be able to choose the perovskite forming material as required by a specific application. For example, the perovskite precursor solution comprises CH₃NH₃PbI₃.

The solution can comprise at least one organic solvent. The solvent can be chosen from non-polar solvents, polar aprotic solvents, or polar protic solvents. In embodiments the solvent is dimethyl sulfoxide (DMSO). In some embodiments, the solvent can be comprise: Acetic acid, Acetone, Acetonitrile, n-Butanol, n-Butyrolactone, n-Pentanol, n-Propanol, n-Octanol, 2-Methyl-2-Propanol, Butylacetate, Chlorobenzene, Chloroform, Cyclohexane, Dichloromethane, Diethylether, 1,2-Dichloroethylene, Diisopropylether, Dimethylacetamide, Dimethylethanolamine, Dioxane, N,N-Dimethylformamide, Dimethyl sulfoxide, Ethanol, Ethylacetate, Ethylene glycol, Ethylmethylketone, Heptane, 15 Hexamethylphosphoramide, Hexane, Isopropylalcohol, 3-Methyl-1-Butanol, Methanol, Methylamine, Methylenechloride, N-methylpyrrolidone, Pentane, n-Propylalcohol, Propylene carbonate, Pentachloroethane, 1,1,2,2-Tetrachloroethane, 1,1,1-Trichloroethane, Tetrachloroethylene, Tetrachloromethane, Tetrahydrofurane, tert-Butanol, Toluene, Trichloroethylene, Water, Xylene, and mixtures thereof.

The mixture can comprise an additive (used to control the crystallization during the perovskite synthesis). In embodiments, the polymer additive is thickening agent. For example, the polymer additive is gellan gum. In embodiments the polymer additive comprises a polymer of the following structure:

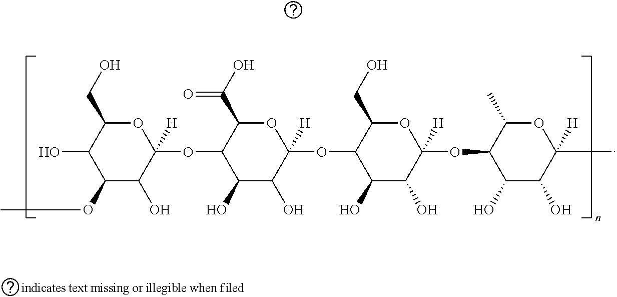

As used herein, the term “gellan gum” can refer to a linear, anionic, extracellular exopolysaccharide secreted by the bacterium Pseudomonas elodea, that consists of repeating tetrassaccharide units composed by two D-glucose, one D-glucuronic acid and one L-rhamnose residue. In embodiments, the gellan gum can comprise gellan gum acetylated (high-acyl) and de-acetylated (low-acyl). High-acyl gellan gum contains two acyl substituents, namely acetate (one acetate group for every two repeat units) and glycerate (one glycerate group for every repeat unit) both located on the same glucose residue, while low-acyl gellan gum is produced by basic hydrolysis and typically contains less than about 5% acyl substituents to no acyl groups. For example, the gellan gum described herein can comprise CAS No. J63423-30.

In embodiments, the polymer additive is present in less than about 2.5 wt. % of the polymer precursor. In embodiments, the polymer additive is present in less than about 1 weight percent (wt. %) of the perovskite precursor. In embodiments, the polymer additive is present in less than about 0.01 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.15 wt. %, about 0.18 wt. %, about 0.2 wt. %, about 0.25 wt. %, about 0.3 wt. %, about 0.35 wt. %, about 0.4 wt. %, about 0.45 wt. %, about 0.5 wt. %, about 0.55 wt. %, about 0.60 wt. %, about 0.65 wt. %, about 0.70 wt. %, about 0.75 wt. %, about 0.80 wt. %, about 0.85 wt. %, about 0.90 wt. %, about 0.95 wt. %, about 0.99 wt. %, about 1.0 wt. %, about 1.25 wt. %, about 1.50 wt. %, about 1.75 wt. %, about 2.0 wt. %, about 2.1 wt. %, about 2.2 wt. %, about 2.3 wt. %, about 2.4 wt. %, about 2.5 wt. %, or greater than 2.5 wt. %. For example, the polymer additive is present in about 0.01 wt. % to about 2.29 wt. % of the polymer precursor. For example, the polymer additive is present in less than about 1.0 wt. % of the polymer precursor. For example, the polymer additive is present in about 0.18 wt. % or about 0.56% weight percent of the perovskite precursors. For example, the polymer additive is present in about 0.56 wt. %.

In embodiments, the depositing comprises blade coating. In embodiments, the blade coater gap comprises less than about 5 μm, about 7.5 μm, about 10 μm, about 15 μm, about 20 μm, about 25 μm, about 50 μm, about 75 μm, about 100 μm, about 125 μm, about 150 μm, about 175 μm, about 200 μm, about 225 μm, about 250 μm, about 275 μm, about 300 μm, about 325 μm, about 350 μm, about 375 μm, about 400 μm, or greater than about 400 μm.

In embodiments, the blade speed comprises about 2.5 mm/s to about 30 mm/s. For example, the blade speed comprises about 0.25 mm/s, about 0.50 mm/s, about 0.75 mm/s, about 1.0 mm/s, about 1.25 mm/s, about 1.50 mm/s, about 1.75 mm/s, about 2.0 mm/s, about 2.5 mm/s, about 5 mm/s, about 7.5 mm/s about 10 mm/s, about 15 mm/s, about 20 mm/s, about 25 mm/s, about 30 mm/s, about 35 mm/s, about 40 mm/s, about 45 mm/s, about 50 mm/s, about 55 mm/s, about 60 mm/s, about 70 mm/s, about 80 mm/s, about 90 mm/s, about 100 mm/s, or greater than about 100 mm/s.

In embodiments, the processing comprises exposure to flame discharge or atmospheric plasma, or thermal annealing. As used herein, the terms “flame discharge” and “flame annealing” can be used interchangeably.

In embodiments, the polymer additive provides resistance against the discharges/energies of the flame, plasma, and/or thermal annealing.

In embodiments, the flame annealing comprises depositing the ink with a printing method described herein or known in the art, passing a flame discharge over the ink after a delay of about 0.1 seconds to about 100 seconds at the speeds and distances described herein. The exact conditions can depend on the material chemistry/composition/solvents used, and would be adjusted accordingly by one of ordinary skill in the art. This process can be amenable to in-line processing. Without wishing to be bound by theory, in a manufacturing method, the flame can remain stationary while the substrate passes under the flame at speeds and distances described herein.

In embodiments, the flame source for the flame annealing can be any source known in the art. For example, the flame source can comprise a butane flame source, a propane flame source, or natural-gas flame source. In embodiments, the flame can pass over the sample at speeds of about 0.1 m/min to 1000 m/min with a distance ranging from about 0.1 cm to about 10 cm.

In embodiments, the flame can pass over the sample with speeds comprising about 0.1 m/min to about 1000 m/min. For example, the exposure comprises less than about 0.01 m/min, about 0.01 m/min, about 0.025 m/min, about 0.05 m/min, about 0.075 m/min, about 0.1 m/min, about 0.25 m/min, about 0.5 m/min, about 0.75 m/min, about 1 m/min, about 2.5 m/min, about 5 m/min, about 7.5 m/min, about 10 m/min, about 12.5 m/min, about 15 m/min, about 20 m/min, about 25 m/min, about 30 m/min, about 40 m/min, about 50 m/min, about 60 m/min, about 70 m/min, about 80 m/min, about 90 m/min, about 100 m/min, about 125 m/min, about 150 m/min, about 175 m/min, about 200 m/min, about 225 m/min, about 250 m/min, about 275 m/min, about 300 m/min, about 325 m/min, about 350 m/min, about 375 m/min, about 400 m/min, about 450 m/min, about 500 m/min, about 550 m/min, about 600 m/min, about 650 m/min, about 700 m/min, about 750 m/min, about 800 m/min, about 850 min/min, about 900 m/min, about 950 m/min, about 1000 m/min, about 1100 m/min, about 1200 m/min, about 1300 m/min, about 1400 m/min, about 1500 m/min, about 1750 m/min, about 2000 m/min, or greater than 2000 m/min.

In embodiments, the sample can be exposed to the flame at a distance of about 0.1 cm to about 10 cm. For example, the distance can comprise less than about 0.01 cm, about 0.01 cm, about 0.025 cm, about 0.05 cm, about 0.075 cm, about 0.1 cm, about 0.25 cm, about 0.5 cm, about 0.75 cm, about 1.0 cm, about 1.25 cm, about 1.5 cm, about 1.75 cm, about 2.0 cm, about 2.25 cm, about 2.5 cm, about 2.75 cm, about 3.0 cm, about 3.25 cm, about 3.5 cm, about 3.75 cm, about 4.0 cm, about 4.25 cm, about 4.5 cm, about 4.75 cm, about 5.0 cm, about 5.25 cm, about 5.5 cm, about 5.75 cm, about 6.0 cm, about 6.25 cm, about 6.5 cm, about 6.75 cm, about 7.0 cm, about 7.25 cm, about 7.5 cm, about 7.75 cm, about 8.0 cm, about 8.25 cm, about 8.5 cm, about 8.75 cm, about 9.0 cm, about 9.25 cm, about 9.5 cm, about 9.75 cm, about 10.0 cm, about 10.25 cm, about 10.5 cm, about 10.75 cm, about 11.0 cm, about 11.25 cm, about 11.5 cm, about 11.75 cm, about 12.0 cm, about 13.0 cm, about 14.0 cm, about 15.0 cm, or greater than about 15.0 cm.

In embodiments, the thermal annealing comprises exposure to about 100° C. for about 25 minutes. In embodiments, the method does not require a quenching step. In embodiments, the thermal annealing comprise exposure to about 100 C to about 350 C and from about 5 to about 120 minutes.

In embodiments, the perovskite material has improved fracture energy compared to a solution-processed material. For example, the fracture energy can be greater than about 6.0 J/m². For example, the fracture energy can be about 6.6+/−2.5 J/m² to about 10.9+/−2.3 J/m².

Because the final morphology of the PVSK is dependent on the balance of the nucleation and growth regimes, controlling the rate of supersaturation during processing is an exciting feature described herein. For example, tuning the morphology of the perovskite material can comprise adjusting the concentration of the polymer additive to reduce the amount of nucleation. For example, depending on the amount of additive used, the LaMer curve can shift accordingly. Higher additive concentrations can reduce the amount of nucleation to the point where morphology with domains >1 mm. For example, methods described herein can be used to tune the morphology to produce small grains, large domains, and/or dendritic structures. For example, as used herein, small grains can comprise about 1 to about 1000 nm. For example, as used herein, large domains can comprise about 1 μm to about 1000 μm or greater. For example, methods described herein can improve the uniformity of the domains.

In embodiments, the domains of the perovskite materials described herein can comprise about 0.0001 mm to about 1.0 mm. For example, the domains can be less than 0.0001 mm, about 0.0001 mm, about 0.00025 mm, about 0.0005 mm, about 0.00075 mm, about 0.001 mm, about 0.0025 mm, about 0.005 mm, about 0.0075 mm, about 0.01 mm, about 0.025 mm, about 0.05 mm, about 0.075 mm, about 0.1 mm, about 0.25 mm, about 0.5 mm, about 0.75 mm, about 1.0 mm, about 1.25 mm, about 1.5 mm, about 1.75 mm, about 2.0 mm, or great than about 2.0 mm.

In embodiments, the perovskite material can have a root mean square roughness value of less than about 1.0 nm, about 1.0 nm, about 1.5 nm, about 2.0 nm, about 2.5 nm, about 3.0 nm, about 3.5 nm, about 4.0 nm, about 4.5 nm, about 5.0 nm, about 5.5 nm, about 5.6 nm, about 5.7 nm, about 5.8 nm, about 5.9 nm, about 6.0 nm, about 6.5 nm, about 7.0 nm, about 8.0 nm, about 8.5 nm, about 9.0 nm, about 9.5 nm, about 10.0 nm, about 10.5 nm, about 11.0 nm, about 11.5 nm, about 12.0 nm, about 12.5 nm, about 13.0 nm, about 13.5 nm, about 14.0 nm, about 14.5 nm, about 15 nm, about 15.5 nm, about 16.0 nm, about 16.5 nm, about 17.0 nm, about 17.5 nm, about 18.0 nm, about 18.5 nm, about 19.0 nm, about 19.5 nm, about 20 nm, about 20.5 nm, about 21.0 nm, about 22.0 nm, about 23.0 nm, about 24.0 nm, about 25.0 nm, about 27.5 nm, about 30.0 nm, about 32.5 nm, about 35.0 nm, about 37.5 nm, about 40.0 nm, about 42.5 nm, about 45.0 nm, about 47.5 nm, about 50 nm, or greater than 50 nm.

In embodiments, the perovskite material has improved optoelectronic properties. For example, the perovskite material can a carrier lifetime of greater than about 1 μs.

In embodiments, the perovskite has increased resistance against heat and humidity. For example, methods described herein can produce compositions which have improved retention of their photoreactive phase after moisture exposure.

Aspects of the disclosure are related to a perovskite material produced by the methods described herein. In embodiments, the perovskite material can be utilized within the photonic field. For example, the perovskite material can be used to form efficient photoactive layers in an inverted PEDOT:PSS solar cell device.

In embodiments, the semiconductor/optoelectronic/photonic device can comprise a photovoltaic device. In some embodiments, the semiconductor/optoelectronic/photonic device can be other than a photovoltaic device and can be for instance a light-emitting diode (LED), a ferroelectric device (BaTiO₃), a superconductor device (YBaCuO₃) (broadly speaking, any ionic conductivity device).

The term “semiconductor device”, as used herein, can refer to a device comprising a functional component which comprises a semiconductor material. This term can be understood to be synonymous with the term “semiconducting device”. Examples of semiconductor devices include a photovoltaic device, a solar cell, a photo detector, a photodiode, a photosensor, a chromogenic device, a transistor, a light-sensitive transistor, a phototransistor, a solid state triode, a battery, a battery electrode, a capacitor, a super-capacitor, a light-emitting device, a laser or a light-emitting diode.

The term “optoelectronic device”, as used herein, can refer to devices which source, control or detect light. Light is understood to include any electromagnetic radiation. Examples of optoelectronic devices include photovoltaic devices, photodiodes (including solar cells), phototransistors, photomultipliers, photoresistors, and light emitting diodes.

In an optoelectronic device such as a photovoltaic device, the perovskite layer is a part of the photoactive region which comprises: An n-type region comprising at least one n-type layer; a p-type region comprising at least one p-type layer; a layer of an intrinsic, undoped perovskite semiconductor, wherein this latter has a band gap between 0.5 and 3.0 eV. In embodiments, the bandgaps of PVSKs described herein are tunable.

As used herein, the term ‘n-type region’, refers to a region of one or more electron-transporting materials. Similarly, the term ‘n-type layer’ refers to a layer of an electron-transporting material. An electron-transporting material could be a single electron-transporting compound or elemental material, or a mixture of two or more electron-transporting compounds or elemental materials. An electron-transporting compound or elemental material can be undoped or doped with one or more dopant elements.

As used herein, the term ‘p-type region’ refers to a region of one or more ion or hole-transporting materials. This region comprises a p-type layer and occasionally a p-type exciton blocking layer. The term ‘p-type layer’ refers to a layer of an ion or hole-transporting material. An ion or hole-transporting material could be a single ion or hole-transporting compound or elemental material, or a mixture of two or more ion or hole-transporting compounds or elemental materials. An ion or hole-transporting compound or elemental material can be undoped or doped with one or more dopant elements.

### EXAMPLES

Examples are provided below to facilitate a more complete understanding of the invention. The following examples illustrate the exemplary modes of making and practicing the invention. However, the scope of the invention is not limited to specific embodiments disclosed in these Examples, which are for purposes of illustration only, since alternative methods can be utilized to obtain similar results.

### Example 1

### Manufacturing Stable Halide Perovskites in Open Air with Flame Curing

### Abstract

A gum-based polymer additive in a semiconducting halide perovskite ink for scalable open-air flame processing of in-line thin film photovoltaic manufacturing is described herein. The additive improves the printability and processability of the ink to be compatible with rapid high-temperature processing.

### Introduction

Aspects described herein are surprising improvements upon a “method for forming perovskite layers using atmospheric pressure plasma” (U.S. Pat. No. 10,636,632B2) where the deposition of perovskite ink is followed by an atmospheric pressure plasma that efficiently cures the precursor to provide the desired perovskite film. This work is in the field of renewable energy materials, manufacturing, and sustainability in an effort to expand on low-cost domestic solar technology.

### Non-Limiting Description

Unmodified perovskite inks designed for conventional solution processing based on spin coating produce pinholed, uneven, and shunted films when processed in air or with scalable processing methods. Polymeric modifiers have been used to improve film uniformity and density. These additives not only act as rheological modifiers by increasing ink viscosity, thus allowing longer periods for crystallization and smooth films, but the long chains of the polymer create an organizational scaffold that increases resistance to humidity. Furthermore, additives from the food industry, such as corn starch, can enhance mechanical integrity and the operational lifetime of devices in addition to inducing spherulitic domains that can be tuned in size by temperature and precursor concentration to increase performance.

Aspects of our invention are directed towards incorporation of nontoxic starch and gum-based materials from the food industry, are studied as additives on improving perovskite quality and manufacturability using scalable, one-step processing in open air. The use of a nontoxic solvent system further extends the wetting period, thus improving crystallization control. The invention also incorporates a high-temperature flame discharge to rapidly crystallize the perovskite, and the use of the additive enables the ability to adapt these rapid process conditions.

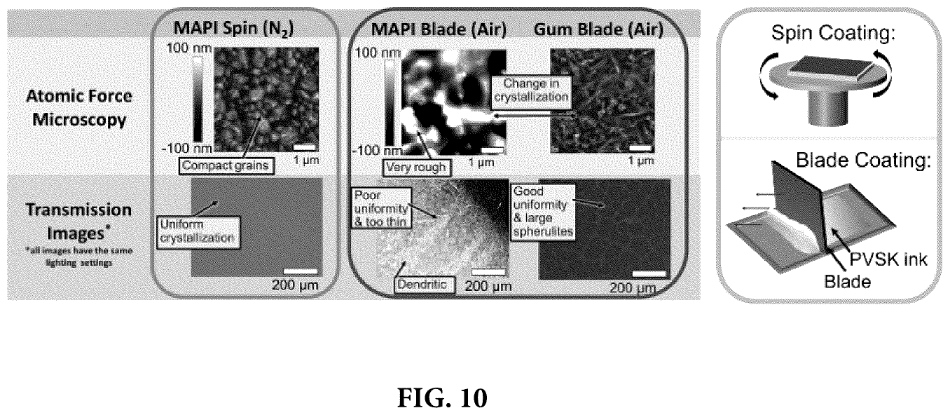

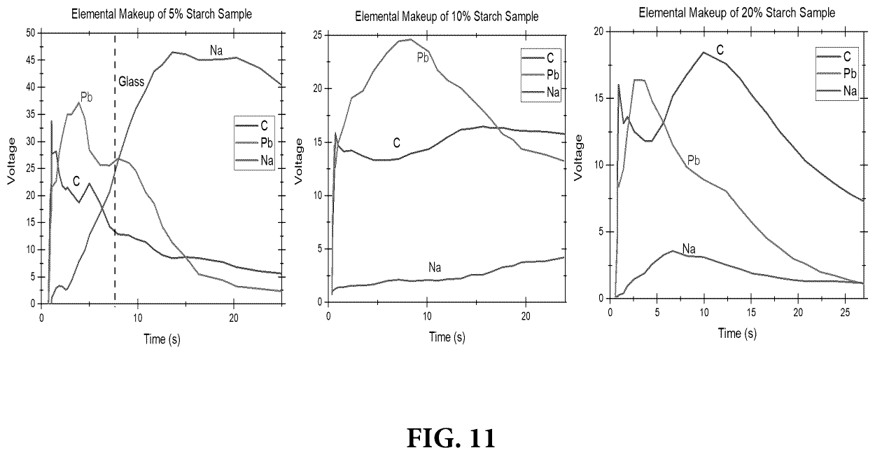

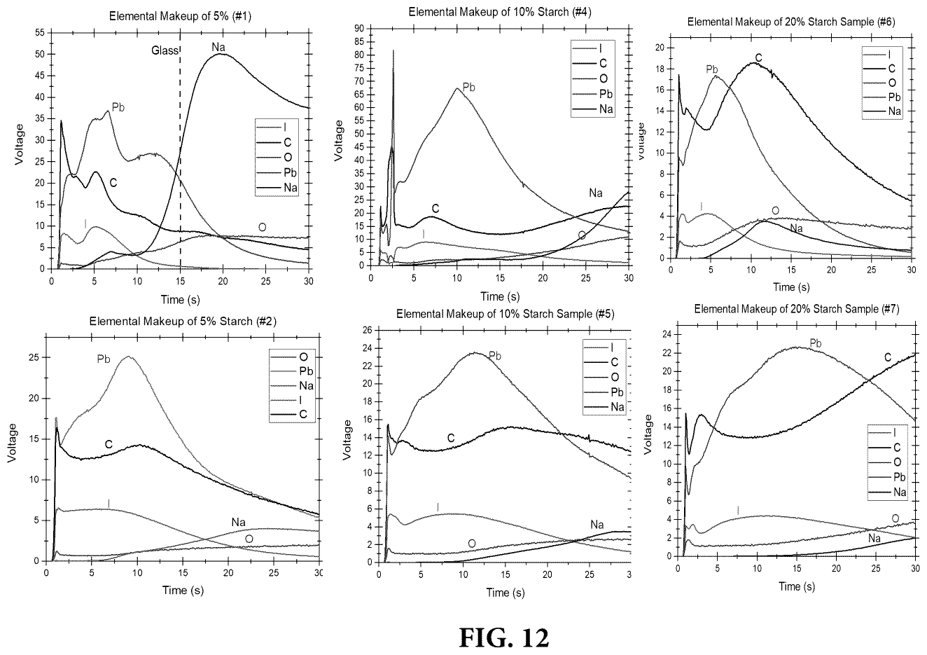

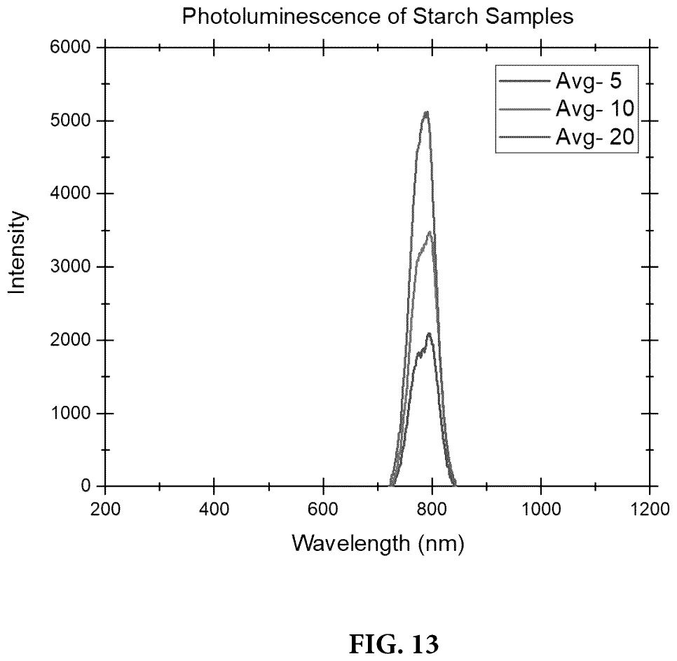

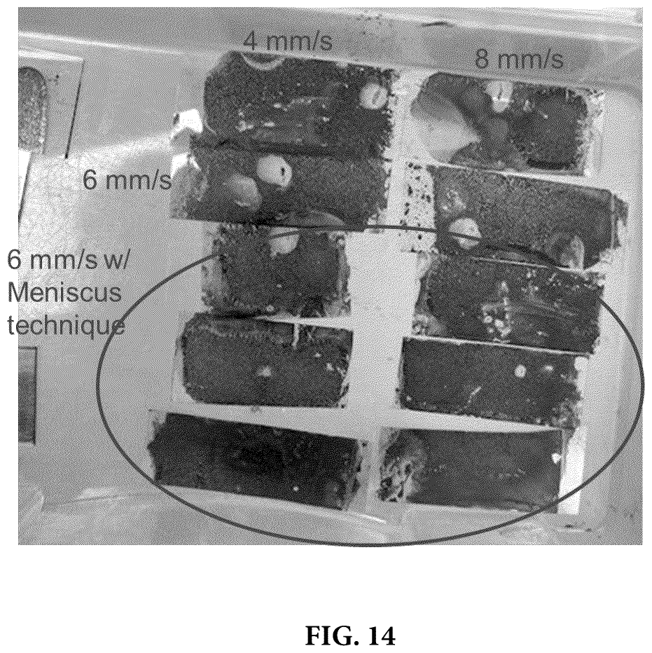

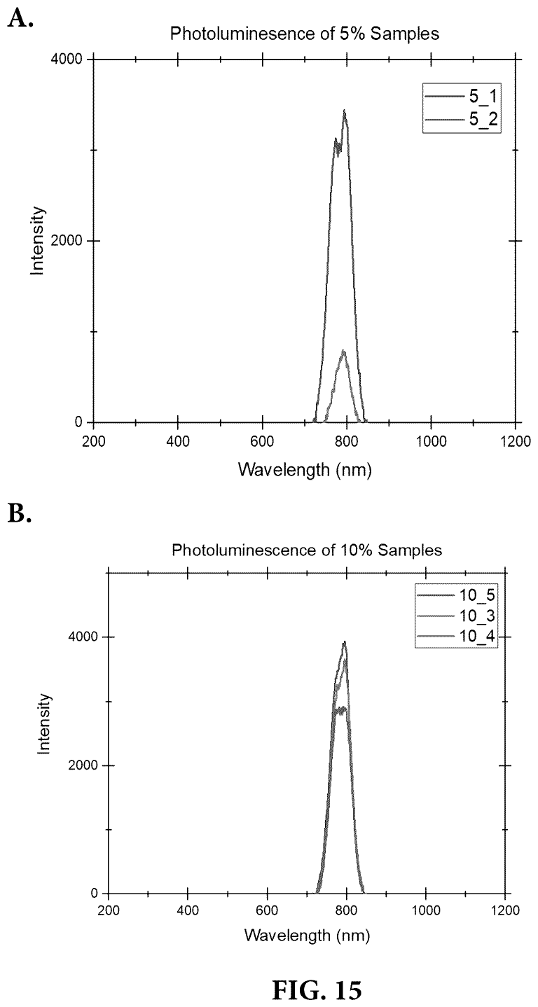

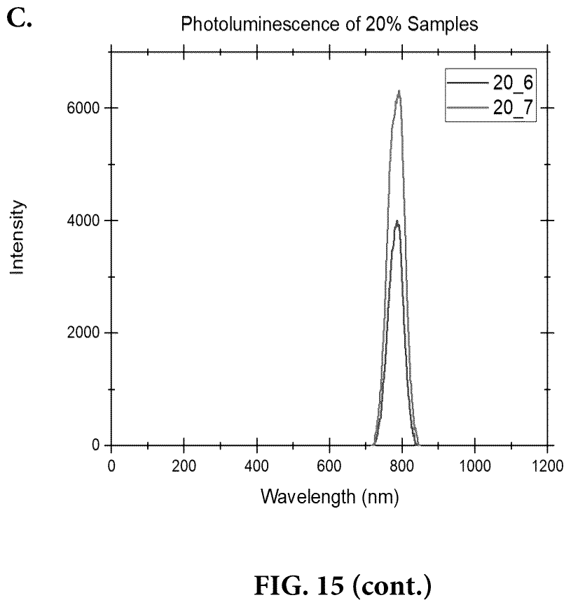

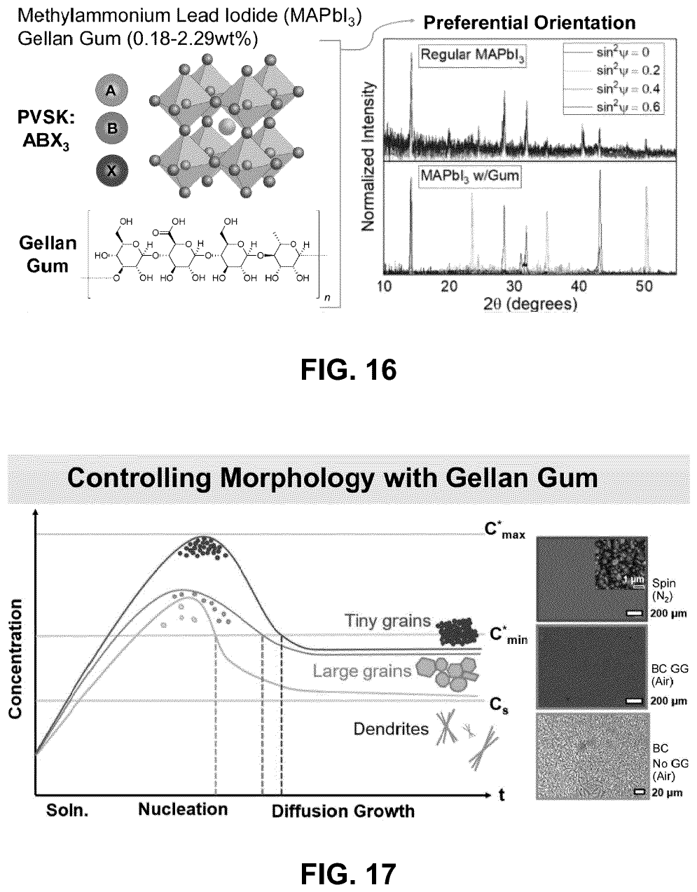

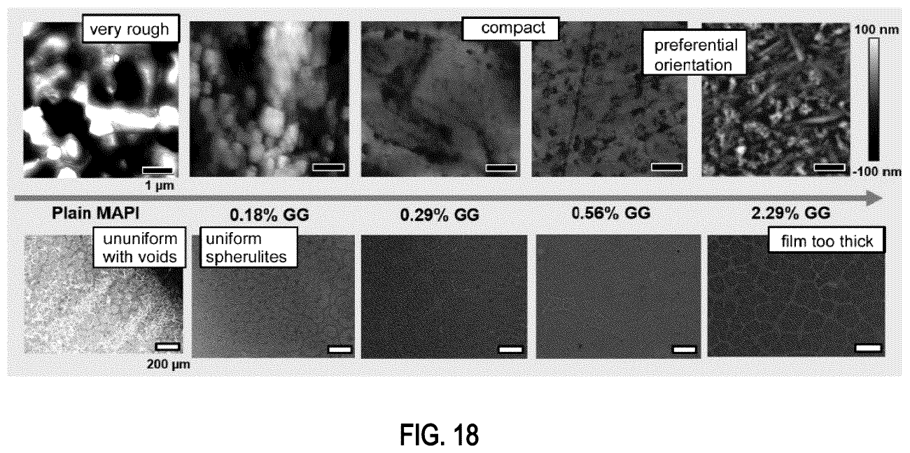

FIG. 10 indicates the non-limiting exemplary effects of scalable processing (blade coating) with a polymer additive.

This technology addresses several challenges that need to be overcome within the field of perovskite photovoltaics, particularly with regards to material processing and device reliability:

### Material Processing

High-rate deposition: This process forms the perovskite in less than one-hundredth the time of typical solution-processed material.
Open Air: deposition occurs in an open-air environment, unlike typical solution-processed materials. Despite the presence of moisture during synthesis, the material performs competitively or superior to other methods.
Low cost raw materials: raw materials usage is significantly lower (50×) compared to the spin-coated method thanks to a very high conversion yield. In addition, the flame is operated with very amounts of natural gas or propane, further promoting an inexpensive process that is 1000s of times higher in throughput and >10× cheaper than conventional, silicon-based solar technology.
Roll-to-roll/in-line manufacturing: a special consequence and an additional advantage which is created by considering all of the previous advantages, is a process which is extremely amenable to roll-to-roll and high volume manufacturing of lightweight solar technology. Integration into tandem devices becomes very straightforward as well.

### Thermomechanical Reliability

Fracture energy: the formed perovskite shows outstanding mechanical properties with a tenfold increase in fracture energy compared to typical solution-processed material. The near-instantaneous cure results in an extremely tough grain structure, which is significantly more resistant to fracture.
Film stress: the perovskite has a tunable and compressive film stress which leads to significantly increased reliability.

The two non-limiting, exemplary properties of the invention are the incorporation of the polymer additive in the perovskite ink in the first step of the process for depositing a high quality and uniform ink and the use of a flame discharge to provide a high energy source for extremely fast conversion of the ink to a high quality thin film.

### Non-Limiting, Exemplary Advantages

We are able to control and tune the morphology of the perovskite film to achieve much larger grain sizes (˜mm scale) compared to conventional processing techniques (μm scale), an effect which improves both optoelectronic and mechanical properties. We measure the film stress to be tunable and compressive based on the additive concentration. We find that the additive enables reproducible and scalable perovskite devices to be produced in ambient conditions that match state-of-the-art performance on manufacturing scales. The devices are stable under both thermal cycling and continuous operation. Without wishing to be bound by theory, the compressive stress in the films along with significantly reduced ion migration based on impedance spectroscopy and transient photocurrent measurements as can be reasons for the improved device stability. These effects can be indicated through aging perovskites with different film stresses and additive concentrations for mechanistic understanding of how film stress influences ion migration and device stability.

### Non-Limiting, Exemplary Commercial Applications

Companies working in the development of the next generation solar cell panels can be interested by this technology. This can include those companies invested in single-junction and tandem markets. The lightweight and extremely low-cost process enables applications in UAVs, drones, satellites, agrivoltaics, trucking (providing energy for refrigeration), residential, commercial, and eventually utility-scale solar installations.

### REFERENCES CITED HEREIN

1. “Method for forming perovskite layers using atmospheric pressure plasma” (U.S. Pat. No. 10,636,632B2)
2. “Rapid open-air fabrication of perovskite solar modules” Rolston et al. Joule, 2020, 4, 12, 2675. (DOI: 10.1016/j.joule.2020.11.001)
3. “Polymer-assisted single-step slot-die coating of flexible perovskite solar cells at mild temperature from dimethyl sulfoxide” Bisconti et al ChemPlusChem 2021, 86, 1442 (DOI: 10.1002/cplu.202100251)
4. “Implication of polymeric template agent on the formation process of hybrid halide perovskite films” Giuri et al, Nanotechnology 2021, 32, 265707 (DOI: 10.1088/1361-6528/abed72)

### Example 2

### Manufacturing Stable Halide Perovskites in Open Air with Flame Curing

### Non-Limiting, Exemplary Disclosure Summary

The technology is a gum-based polymer additive in a semiconducting halide perovskite ink for scalable open-air flame processing of in-line thin film photovoltaic manufacturing. Conventional unmodified perovskite inks designed for conventional solution processing based on spin coating produce pinholed, uneven, and shunted films when processed in air or with scalable processing methods. Polymeric modifiers have been used to improve film uniformity and density. These additives not only act as rheological modifiers by increasing ink viscosity, thus allowing longer periods for crystallization and smooth films, but the long chains of the polymer create an organizational scaffold that increases resistance to humidity. The present invention incorporates non-toxic starch and gum-based materials from the food industry. The additive improves the printability and processability of the ink to be compatible with rapid high-temperature processing. The use of a nontoxic solvent system further extends the wetting period, thus improving crystallization control. The invention also incorporates a high-temperature flame discharge to rapidly crystallize the perovskite, and the use of the additive enables the ability to adapt these rapid process conditions. The formed perovskite exhibits a 10× increase in fracture energy, an extremely tough grain structure, and tunable and compressive film stress compared to typical solution-processed materials.

### Non-Limiting, Exemplary Surprising Features of the Disclosure

Use non-toxic starch and gum-based materials as additives to perovskites for photovoltaic applications.
Faster and lower cost processing methods.

Perovskite films using a food industry-based polymeric additive are described herein.

### Example 3

### Scalable, Quench-Free Processing of Metal Halide Perovskites in Ambient

### Abstract

Described herein is the inclusion of a polymeric saccharide additive, gellan gum (GG), for controlling the crystallization of halide perovskite films. GG enables open-air blade coating of scalable perovskite films with improved morphology and optoelectronic properties in ambient without a quench step compared to films spin coated in a glovebox with antisolvent. We tune the amount of GG in the perovskites precursor and study the interplay between GG concentration and processability, morphological control, and increased stability under humidity, heat, and mechanical testing. The simplicity of implementing this approach and insensitivity to environmental conditions enables a wide process window for the production of low-defect, mechanically robust, and operationally stable perovskites with fracture energies among the highest obtained for perovskites.

### Introduction

The halide perovskite (PVSK) family of materials proves to be the rising star in the next generation of solar devices with lab reported power conversion efficiencies (PCE) rivaling commercial silicon modules at 26.1% after just over ten years of research [1]. Additionally, the compositionally tunable bandgap of PVSK films offers an attractive means of advancing silicon modules when used in tandem, making the push towards scalability increasingly urgent. While PVSK technologies show great promise, the U.S. Department of Energy continues to consider manufacturability, stability, and scalability as key challenges in the effort to reach commercialization [2].

In an effort to address these challenges and move from lab-to-fab, emphasis has shifted from processing via spin coating to innovating scalable techniques such as spray coating, electrochemical deposition, ink jet printing, slot die coating, and doctor-blade coating [3-5]. Meniscus driven doctor-blade coating offers a promising lab-scale deposition method that easily translates to industrial manufacturing techniques such as slot die coating and roll-to-roll manufacturing on flexible substrates. However, this transition from spin coating to meniscus driven processing is often complicated by an incompatibility with inks optimized for use with traditional antisolvent quenching. Tuning parameters associated with alternative quenching methods such as gas or vacuum-based techniques further complicates process optimization, reproducibility, and the overall feasibility of commercialization. Entire studies have been dedicated to reproducibility of these methods [6].

Furthermore, transitioning from lab style inert fabrication to industrial ambient manufacturing poses further complications. Open-air, antisolvent free blade coating of unmodified PVSK inks optimized for spin coating in an inert environment with an antisolvent produces void filled, uneven, and shunted films, demonstrating that the mild annealing step alone is not enough to control crystallization [3,7,8]. Solvent engineering and polymeric modifiers can be used to improve film uniformity, density, and stability while also improving manufacturability through an increase in ink viscosity which offers improved fluid dynamics and crystallization while blade coating [9-11]. Furthermore, biopolymers from the food industry, such as cornstarch, can enhance mechanical integrity and the operational lifetime of devices in addition to inducing spherulitic domains that can be tuned in size by temperature and precursor concentration to increase PCEs while a contemplated organizational scaffolding increases resistance to humidity [12-14].

The biopolymer chosen for this study, gellan gum—a non-toxic extracellular polysaccharide produced from bacteria known as Sphingomonas elodea—forms firm, transparent gels in the presence of metallic ions and features heat resistance properties [15,16]. Without wishing to be bound by theory, gellan gum can mediate the gelation process by undergoing a reversible transition from a disordered single chain to a self-assembled highly ordered double helix upon cooling through crosslinking structures, whereby various fibrous formations are possible depending on temperature, cation attachment, and concentration introduced [16]. Outside of being used as a suspension agent, binder, and coagulant in the food industry, gellan gum can be used field to create films without interrupting expected electrical properties [17,18]. For example, gellan gum has been incorporated into mixed halide perovskites in a polymer mediated crystallization process to achieve devices with equivalent PCEs and improved photostability compared to reference cells [19]. The addition of gellan gum has can also induce an intrinsic compressive stress within the perovskite film, a property correlated with improved mechanical and environmental stability [20,21].

Rather than directly controlling solvent evaporation with an antisolvent, air-gun, or the use of heat, gellan gum alters fluid dynamics and free energy considerations within the ink to tune the crystallization process by acting as a barrier to excessive homogenous and early heterogeneous nucleation through intermediate interactions and a change in wetting angle thanks to rheological modification. These factors stimulate radial, spherulitic growth of similarly oriented domains that grow in a space filling nature that combats the presence of pinholes while possibly collecting defects and impurities, including the additive, along grain boundaries which can assist in relieving detrimental thermal or intrinsic stresses associated with the thermal expansion mismatch between the PVSK layer and substrate without inhibiting optoelectronic properties [10, 20].

Described herein is a method of polymer mediated crystallization enabling high quality blade coated methylammonium lead iodide, CH₃NH₃PbI₃ (MAPI), films in open air without quenching that feature improved mechanical, optoelectronic, and stability characteristics. With the introduction of less than one weight percent of gellan gum, we describe that the crystallization process can be fully controlled, which allows tuning of the perovskite film morphology according to additive concentration. This tunability can be enabled by controlling supersaturation rates of the evaporating wet film, which thereby changes the balance between the nucleation and growth regimes involved in the overall crystallization process [10, 20].

### Results and Discussion

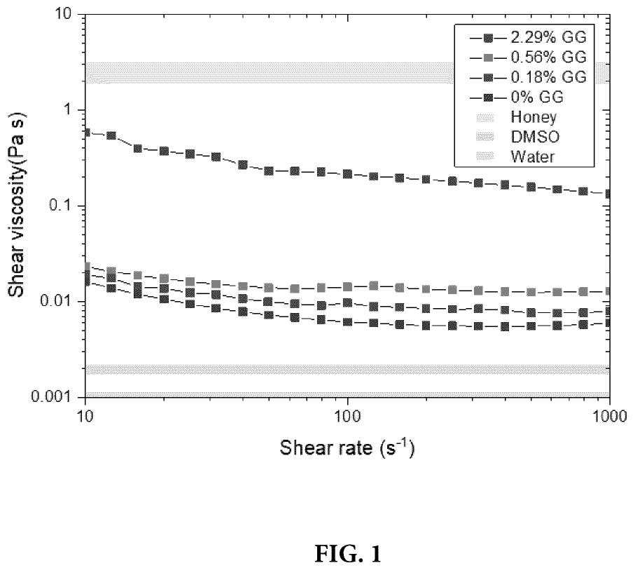

We tested several concentrations of MAPI-x % gellan gum (GG), where x % GG is the weight percent of gum to perovskite precursors. For example, 0.18% corresponds to 1.1 mg of GG in 1 mL of MAPI. Note that the ratio of perovskite precursor to dimethyl sulfoxide (DMSO) remained the same for all inks, 28 wt %. As seen in FIG. 1, higher concentrations of GG, such as 2.29%, approach the viscosity of honey and feature stronger pseudo-plastic behavior, which requires significantly slower coating speeds (below 2.5 mm/s) to achieve desired 500 nm thick films compared to lower gum concentrations like 0.56% and 0.18% which behave more like Newtonian fluids with constant viscosity at a given temperature and can be coated at faster speeds (upwards of 25 mm/s) that are needed for commercial viability. In addition to altering processing parameters, an increased concentration of GG slows film conversion by altering the crystallization process and the resulting final film morphology due to the polymer's interactions with the solvent and precursor materials. Additionally, GG acts as an especially efficient thickener compared to other polysaccharide additives such as cornstarch which require more than 10 wt. % to achieve similar shear viscosities to 0.56% GG [12].

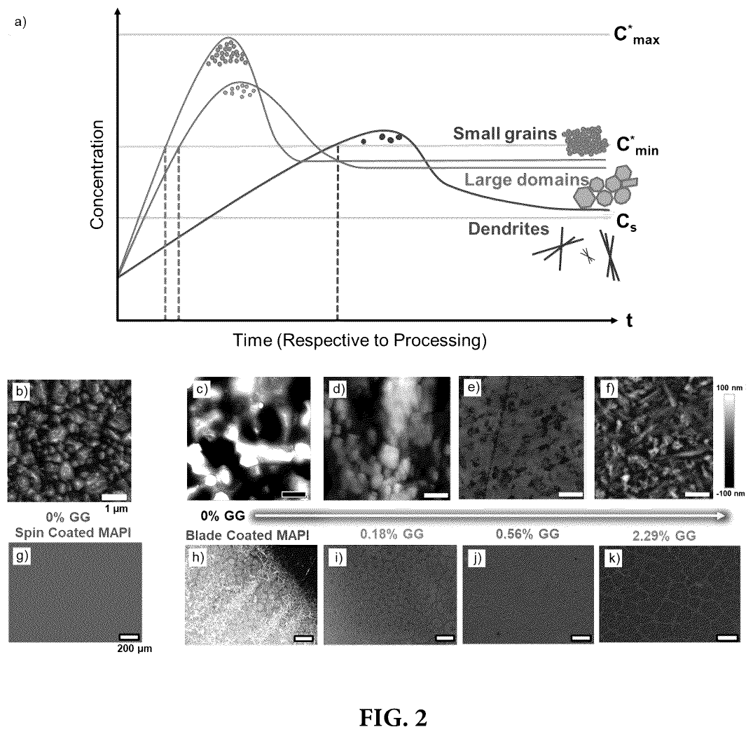

After identifying the rheological properties of GG, we then studied the effect of viscosity on PVSK crystallization. While the exact mechanisms of the PVSK crystallization process remain an active area of research, the LaMer theory, a qualitative analogy which builds upon Classical Nucleation Theory to describe the removal of solvent from a simplified monodispersed crystalline nanoparticle system is, without wishing to be bound by theory, presented as a link between theory and processing [5,14,22-27]. The LaMer curve can be plotted with concentration versus time respective to the nucleation and growth regimes to describe their respective dominance and influence on morphology, yet this plot is not always intuitive from a processing point of view. FIG. 2 panel a presents a modified visualization of the classic LaMer curve, where concentration is plotted against processing time for complete film conversion. The plot begins with the initial drying process whereby the removal of solvent from the wet film increases the concentration of the remaining liquid to saturation, Cₛ, at a near constant rate before reaching a critical supersaturation concentration, C*, between C*ₘᵢₙ and Cₘₐₓ* whereby stable nucleates are likely to form. Once nucleation occurs, the available precursor concentration in solution will drop below C*ₘᵢₙ into a regime dominated by crystal growth until all available liquid is removed. Because the final morphology of the PVSK is dependent on the balance of the nucleation and growth regimes, controlling the rate of supersaturation during processing is an exciting feature described herein.

For example, the red curve in FIG. 2 panel a corresponds to spin coating with an antisolvent, which induces sudden film conversion due to the high rate and degree of supersaturation achieved which results in instantaneous burst nucleation because of the targeted solvent removal. This fast, uniform, and dense burst nucleation scenario creates fine-grained morphologies such as the film in FIG. 2 panels b and g which were captured via tapping mode atomic force microscopy (AFM) and transmission optical microscopy respectively. On the other extreme, as seen in grey in FIG. 2 panel a, if the degree and rate of supersaturation are low then conversion of the film will be slow due to a lesser driving force in the creation of stable nucleates as prolonged growth will occur at these fewer existing sites. This slow process yields rough dendritic films with many voids like the antisolvent-free blade coated 0% GG film in FIG. 2 panels c and h.

GG enables modulation between these two extremes. The green curve in FIG. 2 panel a corresponds to the polymer mediated process where sufficiently dense burst nucleation ensures complete coverage while reserving time and nutrients for domain growth. The AFM image in FIG. 2 panel d and the corresponding transmission image in FIG. 2 panel i show the increase in grain size with 0.18% GG versus ultra-fast antisolvent quenching in FIG. 2 panel b as suggested by the LaMer curve. Likewise, at an optimized concentration of 0.56% GG, AFM images in FIG. 2 panel e and the corresponding transmission image in FIG. 2 panel j reveal that large, uniform spherulitic domains and a compact surface morphology are favored, which may create a better interface with transport layers deposited after the active layer in solar devices. Interestingly, AFM and transmission images in FIG. 2 panels f and k demonstrate that a high concentration of GG can delay the onset of both homogeneous and heterogeneous nucleation much longer than 0.56% GG ink, with one such source of this delay resulting from the increased viscosity which can slow species diffusion rates critical to the overall crystallization process, such that even a lower supersaturation rate stimulates a dense burst-like nucleation event accompanied by extra time for crystallite growth into textured dendritic microstructures while retaining the overall morphology and uniformity of spherulitic domains. While this surface texturing is accompanied by visually continuous films, 0.56% GG was selected as the upper threshold for our following experiments due to its decrease in root mean square roughness from 19.2 nm in the spin coated control film to 11.2 nm which offers a promising interface for the deposition of thin charge transport layers that will be fabricated on top of the PVSK film.

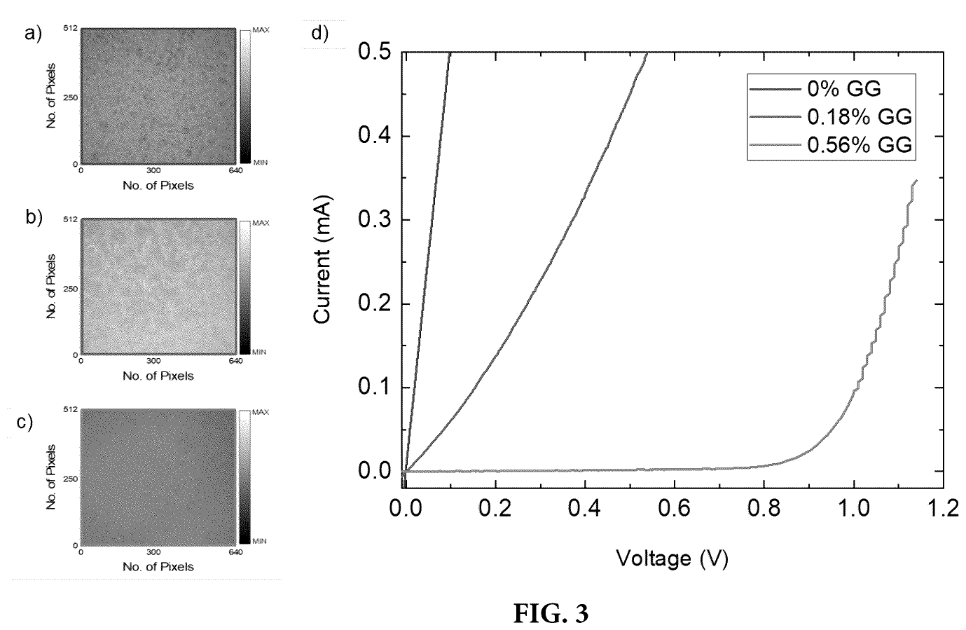

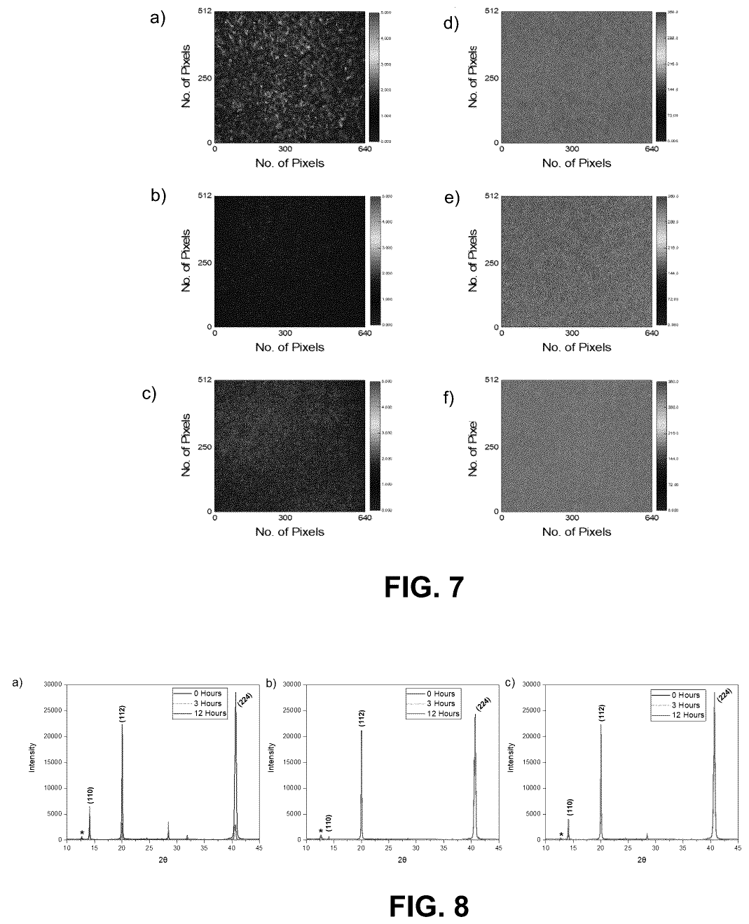

We then performed optoelectronic characterization of the MAPI films as a function of GG concentration. Illuminated lock-in thermography (ILIT) was thus performed on blade coated samples with 0%, 0.18% and 0.56% GG to observe the correlation between morphology changes in the film and thermographic response with the compositions. Thermal topography images from FIG. 3 panels a-c validate the improvement in the uniformity of the deposited film with the addition of the optimum amount of the additive (0.56% GG) to the ink, which is observed as less variation of temperature across the sample as shown in FIG. 3 panel c. Variations in temperature or the presence of dark and bright regions in FIG. 3 panels a and b imply the presence of gaps or morphological variations across the samples observed in the samples with 0% GG and 0.18% GG. Illumination amplitude images from FIG. 7 panels a-c in correlation with illumination phase images from FIG. 7 panels d-f validate the presence of these gaps and the improvement of film uniformity. The presence of extremely bright spots on the illuminated amplitude images corresponds to cither recombination centers or defects. The phase variations on the illuminated phase images show the changes in the depth at those particular points. Based on the above correlations, the reduction of the bright spots on the amplitude image and the reduction in the phase changes on the phase image for the 0.56% GG composition show the improvement in uniformity and optoelectronic response across the sample. These improvements were further validated by electronic characterization when I-V response of these samples was measured (ITO/MAPI/Carbon), where 0% and 0.18% GG did not show any response to the applied voltage and 0.56% GG showed uniform J-V response (FIG. 3 panel d).

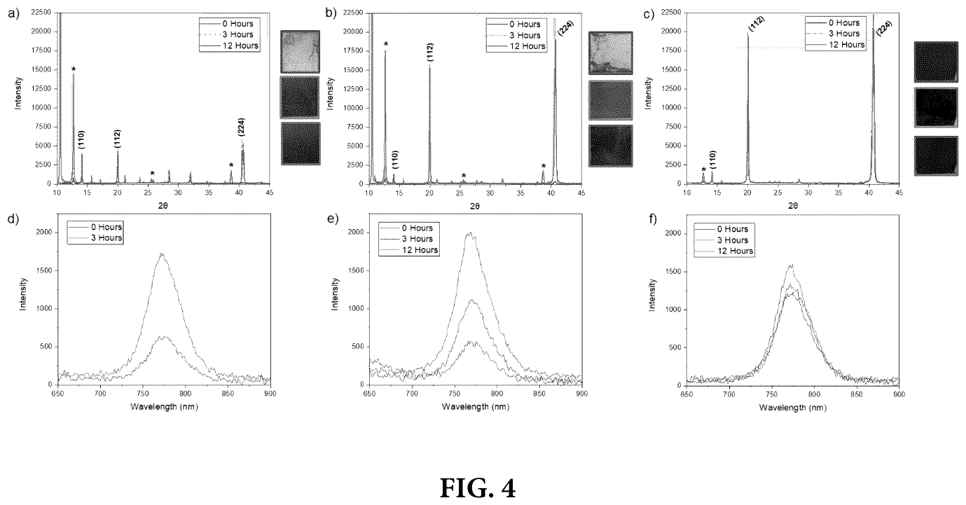

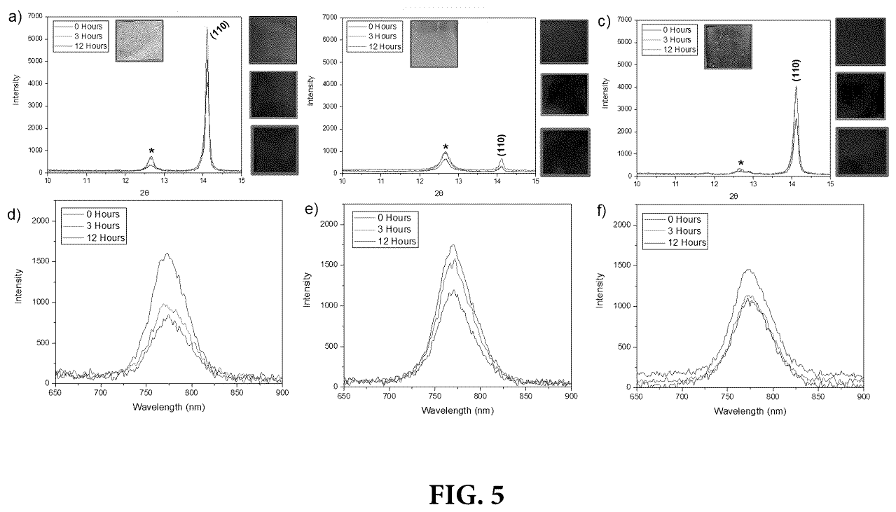

Next, we tested the effects of GG inclusion on the operational stability of MAPI films. X-ray diffraction spectrums and photoluminescent data were collected for unencapsulated MAPI blade coated samples after humidity (25 C, 85% RH) and heat aging (85 C in vacuum) initially and after three hours and 12 hours, as shown in FIGS. 4 and 5. FIG. 4 panels a-c indicates the effects of aging in humid air for 12 cumulative hours with both 0% GG (FIG. 4 panel a) and 0.18% GG (FIG. 4 panel b) featuring a near complete elimination of characteristic perovskite peaks coupled with an increase in peaks associated with lead iodide. This crystallographic evidence suggests the volatilization of the methylammonium cation, possibly as a means of stress relaxation, and PL data in FIG. 4 panels d-e confirms the near complete loss of the black photoreactive phase after 12 hours as seen in the optical images alongside FIG. 4 panels a-b. In contrast, at an optimized concentration of the polymeric additive, 0.56% GG, the film retains its characteristic perovskite peaks and black phase (FIG. 4 panel c) while suppressing excessive lead iodide formation with notably improved retention of the photoreactive phase after 12 hours of moisture exposure (FIG. 4 panel f). This improvement against humidity can likely be attributed to the improved film uniformity and morphology made possible by the alterations in film crystallization induced by the addition of the GG, and this evidence further points towards an induced beneficial compressive stress inherent to the film.

XRD and PL data were then collected for ambient MAPI blade coated samples after aging under vacuum at 85° C. initially and after three hours and 12 hours, as shown in FIG. 5. While XRD evidence of the degradation of the perovskite into lead iodide is not as dramatic as under humid conditions in FIG. 4 which is plotted across a wide 20 axis, FIG. 5 panel c indicates that 0.56% GG can markedly suppress lead iodide formation compared to 0% GG and 0.18% GG (FIG. 5 panels a and b). It is important to also note the dramatic difference in final film quality between 0% GG and the GG samples as seen in inset transmission camera images in FIG. 5 panels a-c, clearly indicating the improved coverage enabled by GG. PL data (FIG. 5 panels d-f) enables a more nuanced evaluation of the optoelectronic degradation across the samples with aging, with both 0% and 0.18% GG films featuring a continuous drop in PL intensity while 0.56% GG retains a higher PL reading with no noticeable loss in intensity between 3 and 12 hours of aging.

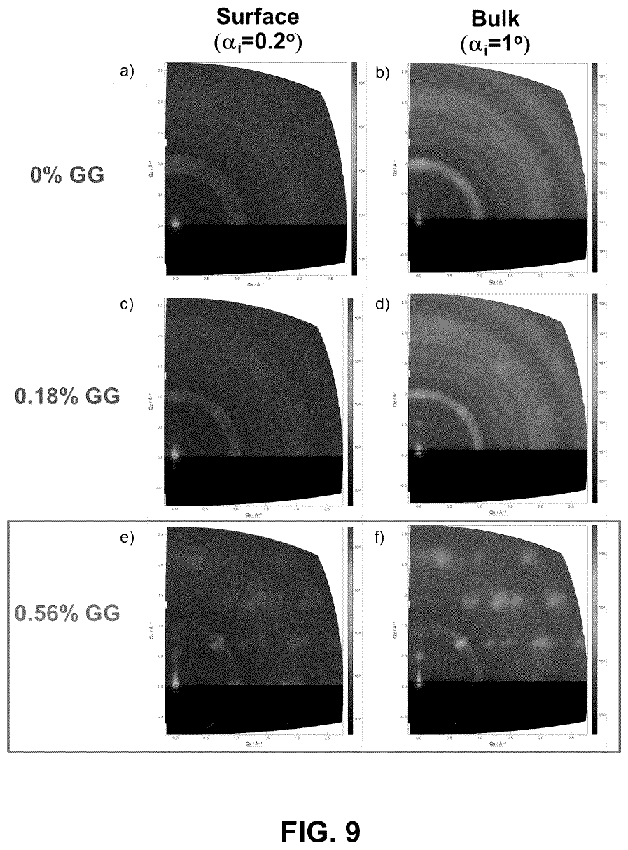

As seen in FIG. 4 panels a-c and FIG. 8, an increasing dominance of the (112) plane located at 2θ of approximately 20° as well as the corresponding (224) plane at approximately 40° over the traditionally dominate (110) MAPI plane in spin coated samples at approximately 14º indicates that blade coated GG films have preferential orientation of the polycrystalline grains that likely arises at least in part to the uniaxial direction of coating. This change in orientation of the PVSK grains is consistent between the surface and bulk as supported by grazing incident wide angle X-ray scattering (GIWAXS) data collected at various penetration depths, and the data confirms an increase in GG leads to partially to highly oriented 3D bulk crystal texturing (FIG. 9). This change in crystal orientation can plays a role in degradation that is thought to correspond to stress relaxation in the perovskite film, and without wishing to be bound by theory, that the defects present and diffusion along grain boundaries likely play a critical role in film degradation and its rate of occurrence. However, some defects may have beneficial effects, with previous evidence of the presence of self-passivated lead iodide between adjacent spherulites at the grain boundaries in blade coated samples being reported, and this might explain the improved stability of GG films over 0% GG samples due to the intensity of lead iodide peaks present relative to PVSK peaks in the GG films at 0 hours in FIG. 4 panels b-c and 5 panels b-c [10].

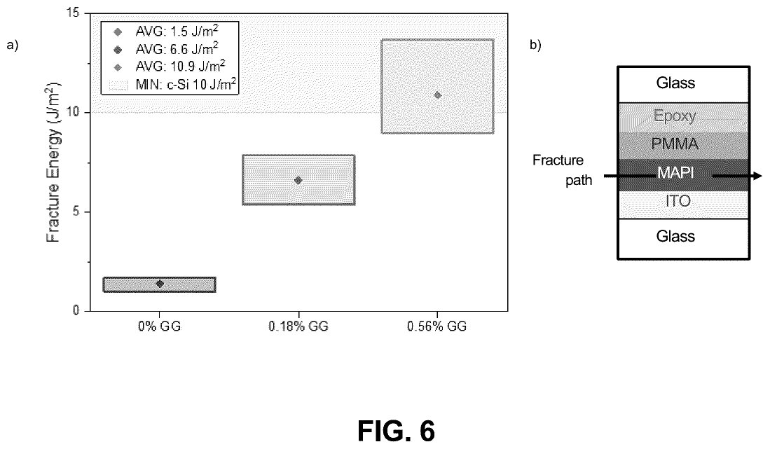

In addition to the improved resistance to aging, without wishing to be bound by theory, the mechanical properties of the GG films can be improved as well. Our previous work validated this in spin coated PVSK with starch additives, where a significant increase in fracture energy was observed with the addition of 10 wt % of starch and above [13]. Double cantilever beam testing was performed on spin coated control and blade coated samples with varying compositions of GG to observe the changes in the fracture energy, G_{c}, of the MAPI films. FIG. 6 panel a indicates that the addition of GG can increase the average G_{c} of the perovskite layer from 1.5±0.2 J/m² for a spin coated control to 6.6±2.5 J/m² with the addition of 0.18% GG and 10.9±2.3 J/m² for 0.56% GG which is among the highest values obtained for perovskites and is comparable with crystalline silicon modules that have a Ge of ˜10 J/m² [28]. A G. of over 5 J/m² has been identified as a critical metric for ensuring durability during handling, a value which is exceeded by both 0.18% and 0.56% GG films [13,28]. Note that a spin coated 0% GG sample was chosen over a blade coated one due to the many voids present in the later (see FIG. 2 panels c and h) which results in fracture outside of the PVSK yielding unrepresentative fracture energies similar to that of the epoxy layer. Mitigating delamination and fracture of the active layer is critical to increasing the overall durability and stability of PVSK solar cells, especially with respect to suppressing pathways to accelerated environmental degradation.

### Conclusions

Our findings indicate that the addition of an optimized concentration of GG, 0.56%, balances the crystal nucleation and growth regimes. As a result, this quench-free polymer-mediated crystallization process of ambient blade coated MAPI thin films induces compact and continuous morphologies. Lock-in thermography and J-V curves indicate the improved optoelectronic properties of the 0.56% GG inclusion. Additionally, increased mechanical integrity is achieved with robust fracture energies indicating resistance to cracking and delamination, and superior optoelectronic and crystalline durability and stability after 12 hours of aging in 85% RH or 85° C.

With the help of the biopolymer additive and efficient meniscus driven blade coating, the crystallization process can be effectively altered. Supersaturation rates can be tuned to produce a unique range of morphologies with variable domain sizes and degrees of surface texturing according to additive concentration and without the use of excessive heat. The result is a reduction of detrimental tensile thermal stresses which can advance degradation in the film. By altering the rheology and free energy considerations of the PVSK ink, radial, spherulitic growth of similarly oriented domains grow in a space filling nature while concentrating defects, impurities, and possibly the additive to domain boundaries. This serves as one possible mechanism of self-passivation behind the improved resilience to heat and humidity aging. Notably, this work shows a systematic means of investigating key stability characteristics derived from a tunable morphology for the scalable, quench free production of mechanically and environmentally robust PVSK films. For the first time, less than one weight percent addition of a polysaccharide biopolymer has been able to convert an ink optimized for use with antisolvent spin coating in an inert environment into a quench free ink capable of being processed in open-air via a scalable deposition method. Without wishing to be bound by theory, an important implication of this work is to accelerate the commercialization of PVSK solar cells through the usage of a single, common PVSK solvent. In doing so, without wishing to be bound by theory, we can enable a scalable manufacturing process of robust perovskite solar cells by having shown how crystallization theory can be leveraged to improve morphology, stability, and durability.

### Materials and Methods

All of the materials were purchased and used as received unless otherwise stated. Methylammonium Iodide (MAI, >99.99%), CH₃NH₃I, was purchased from GreatCell Solar. Lead (II) Iodide, PbI₂ (99.99%), was purchased from TCI. Gellan gum was sourced from Alfa Aesar and was oven dried at 80° C. for 3 days before use and then stored in a nitrogen dry box. The solvent, dimethyl sulfoxide (DMSO, ≥99%), was purchased from Sigma Aldrich. Gellan gum powder was purchased from Alfa Aesar.

The halide PVSK (CH₃NH₃PbI₃) precursor solution was prepared by mixing MAI and PbI₂ in a molar ratio of 1:1 in 1 mL of DMSO in a nitrogen glovebox. This solution was then mixed with a stir bar at 80° C. for 30 minutes. This stock solution was pipetted into separate vials for further DMSO dilution to 0.5M and the addition of various amounts of dried gellan gum, such as 0.18% and 0.56% weight percent of the perovskite precursors. The gellan gum MAPI inks were heated for 2 more hours at 80° C. while being mixed continuously with a stir bar until complete visual dissolution of the gellan gum particles.

Plain or patterned ITO glass substrates were washed with detergent and rinsed with deionized water before being sonicated sequentially in acetone and isopropanol for 5 minutes each. The substrates were dried with a nitrogen gun and UV-ozone treated for 10 minutes before coating. When investigating gum concentrations of 0.56% or less, a ten-minute substrate pre-heating period was allowed if coating on a heated substrate which did not exceed 55° C. The blade coater gap varied from 100-300 μm to accommodate for variations in the glass substrate and ink viscosity while blade speeds ranged from 2.5 mm/s to 30 mm/s. Spin coating was done in a nitrogen glovebox at 4000 rpm for 30 seconds with chlorobenzene as the antisolvent. All films were annealed at 100° C. for 25 minutes.

### Characterization

Bruker Multimode 8 Atomic Force Microscope was used to image the surface of our samples. The images were recorded at a 5 μm×5 μm resolution with a scan rate of 1 Hz and 256 lines/sample. The Keyence VHX-7000 Microscope was used to verify the morphology of the sample using the transillumination settings, and a smartphone was used to record macroscale 1×1 in images.

Illuminated lock-in thermography (ILIT) uses pulsed light and thermal imaging over time to produce thermal amplitude maps of a sample [29,30]. The amplitude of the thermal emission is directly related to the amount of non-radiative recombination occurring at the point; the thermal emission is influenced by the light absorption and lateral carrier transport within the material [30]. ILIT was measured using a modified ThermoSensorik GmbH ThermoSensor. The tool's 4-quadrant power supply was connected to a green LED array from Brightspot Automation which was used to pulse light onto the sample. The image resolution is approximately 5-μm per pixel. Due to uncertainties in the location of the light relative to the sample and in calibration, the absolute amplitude (in mK) is not used in the thermal amplitude maps. Rather, a relative measure of the maximum observed thermal amplitude is used. In this way, we comment on the distribution of thermal emission across the sample, which changes with film morphology, rather than an exact measure of heating at a given point.

The I-V responses of the samples were measured using PAIOS, an all-in-one measurement equipment for photovoltaic devices and LEDs, and photoluminescence (PL) was measured using an in-house BLACK-Comet UV-Vis Spectrometer from StellarNet with a laser wavelength of 425 nm.

The samples were aged in the Thermotron Model SM-8-8200 Environmental Test Chamber, and the fracture data was collected through the use of a double cantilever beam set up which features the Delaminator Adhesion Test System in the configuration. For fracture testing, sandwich-like structures were assembled with perovskite films coated on ITO glass being covered with a protective layer of polymethyl methacrylate (PMMA) which was then epoxied to an additional glass slide. A manually created pre-crack was formed to assist initial crack formation at the perovskite layer during the uniaxial cyclic loading process, and the average G_{c} was calculated from averaging multiple critical load values from the resulting load-displacement curve as the crack propagated along the length of the sample.

Grazing incidence wide angle X-ray scattering (GIWAXS) measurements were performed on a Xenocs Xeuss 3.0 SAXS/WAXS instrument. A GeniX3D Cu High Flux Very Long (HFVL) focus source was used to produce an 8 KeV Cu K alpha collimated X-ray beam with a wavelength of 1.541891 Å (generated at 50 kV and 0.6 mA). A windowless EIGER2 R 1M DECTRIS Hybrid pixel photon counting detector was used to collect the scattering signal at the sample-to-detector distance of 80 mm to cover a Q range between ˜0.5 Å-1 and ˜3.5 Å-1. Default GIWAXS lineup and rectangular beam (0.8 mm×1.2 mm) were used for measuring each sample. Grazing incidence angles were set as 0.2° and 1º. Measuring time was 30 mins for each sample. Q representation images (Qx vs. Qz) were reduced from the obtained images from the 2D detector.

### REFERENCES CITED IN THIS EXAMPLE

1. Liu, C.; Yang, Y.; Chen, H.; Xu, J.; Liu, A.; R Bati, A. S.; Zhu, H.; Grater, L.; Sudhakar Hadke, S.; Huang, C.; et al. Bimolecularly Passivated Interface Enables Efficient and Stable Inverted Perovskite Solar Cells;
2. Office of Energy Efficiency & Renewable Energy. Available Online: Https://Www.Energy.Gov/Eere/Solar/Perovskite-Solar-Cells (Accessed on 1 Jan. 2024).
3. Deng, Y.; Van Brackle, C. H.; Dai, X.; Zhao, J.; Chen, B.; Huang, J. Tailoring Solvent Coordination for High-Speed, Room-Temperature Blading of Perovskite Photovoltaic Films. Sci Adv 2019, 5, doi: 10.1126/sciadv.aax7537.
4. Li, Z.; Klein, T. R.; Kim, D. H.; Yang, M.; Berry, J. J.; Van Hest, M. F. A. M.; Zhu, K. Scalable Fabrication of Perovskite Solar Cells. Nat Rev Mater 2018, 3.
5. Dunlap-Shohl, W. A.; Zhou, Y.; Padture, N. P.; Mitzi, D. B. Synthetic Approaches for Halide Perovskite Thin Films. Rev Chem 2019, 119, 3193-3295, doi: 10.1021/acs.chemrev.8b00318.
6. Kaczaral, S. C.; Morales, D. A.; Schreiber, S. W.; Martinez, D.; Conley, A. M.; Herath, R.; Eperon, G. E.; Choi, J. J.; McGehee, M. D.; Moore, D. T. Improved Reproducibility of Metal Halide Perovskite Solar Cells via Automated Gas Quenching. APL Energy 2023, 1, doi: 10.1063/5.0174396.
7. Zhong, Y.; Munir, R.; Li, J.; Tang, M. C.; Niazi, M. R.; Smilgies, D. M.; Zhao, K.; Amassian, A. Blade-Coated Hybrid Perovskite Solar Cells with Efficiency >17%: An In Situ Investigation. ACS Energy Lett 2018, 3, 1078-1085, doi: 10.1021/acsenergylett.8b00428.
8. Li, J.; Munir, R.; Fan, Y.; Niu, T.; Liu, Y.; Zhong, Y.; Yang, Z.; Tian, Y.; Liu, B.; Sun, J.; et al. Phase Transition Control for High-Performance Blade-Coated Perovskite Solar Cells. Joule 2018, 2, 1313-1330, doi: 10.1016/j.joule.2018.04.011.
9. Zhao, Y.; Wei, J.; Li, H.; Yan, Y.; Zhou, W.; Yu, D.; Zhao, Q. A Polymer Scaffold for Self-Healing Perovskite Solar Cells. Nat Commun 2016, 7, doi: 10.1038/ncomms10228.
10. Bi, Z.; Rodríguez-Martínez, X.; Aranda, C.; Pascual, E.; José, S.; Goñi, A. R.; Campoy-Quiles, M.; Xu, X.; Guerrero, A. Defect Tolerant Perovskite Solar Cells from Blade Coated Non-Toxic Solvents; 2018;
11. Gutwald, M.; Rolston, N.; Printz, A. D.; Zhao, O.; Elmaraghi, H.; Ding, Y.; Zhang, J.; Dauskardt, R. H. Perspectives on Intrinsic Toughening Strategies and Passivation of Perovskite Films with Organic Additives. Solar Energy Materials and Solar Cells 2020, 209, doi: 10.1016/j.solmat.2020.110433.
12. Giuri, A.; Masi, S.; Listorti, A.; Gigli, G.; Colella, S.; Esposito Corcione, C.; Rizzo, A. Polymeric Rheology Modifier Allows Single-Step Coating of Perovskite Ink for Highly Efficient and Stable Solar Cells. Nano Energy 2018, 54, 400-408, doi: 10.1016/j.nanoen.2018.10.039.
13. Giuri, A.; Rolston, N.; Colella, S.; Listorti, A.; Esposito Corcione, C.; Elmaraghi, H.; Lauciello, S.; Dauskardt, R. H.; Rizzo, A. Robust, High-Performing Maize-Perovskite-Based Solar Cells with Improved Stability. ACS Appl Energy Mater 2021, 4, 11194-11203, doi: 10.1021/acsacm.1c02058.
14. Giuri, A.; Vanni, N.; Ahmad, M.; Rolston, N.; Esposito Corcione, C.; Listorti, A.; Colella, S.; Rizzo, A. Incorporation of Functional Polymers into Metal Halide Perovskite Thin-Films: From Interactions in Solution to Crystallization. Mater Adv 2023, 4, 4294-4316.
15. Nishinari, K.; Kremer, L. F.; Lagaly, K. G. Physical Chemistry and Industrial Application of Gellan Gum. Prog Colloid Polym Sci 1999, 114.
16. Grasdalen, H.; Smidsrod, O. Gelation of Geilan Gum; 1987; Vol. 7.
17. Karthika, J. S.; Vishalakshi, B.; Naik, J. Gellan Gum-Graft-Polyaniline—An Electrical Conducting Biopolymer. Int J Biol Macromol 2016, 82, 61-67, doi: 10.1016/j.ijbiomac.2015.10.061.
18. Osmałek, T.; Froelich, A.; Tasarek, S. Application of Gellan Gum in Pharmacy and Medicine. Int J Pharm 2014, 466, 328-340.
19. Bisconti, F.; Leoncini, M.; Bravetti, G.; Giuri, A.; Polimeno, L.; Carallo, S.; Colella, S.; Gatto, L.; Grandi, F.; Cinquanta, E.; et al. Blocking Wide Bandgap Mixed Halide Perovskites' Decomposition through Polymer Inclusion. J Mater Chem C Mater 2023, 11, 12213-12221, doi: 10.1039/d3tc01833d.
20. Ahmad, M.; Cartledge, C.; McAndrews, G.; Giuri, A.; McGehee, M. D.; Rizzo, A.; Rolston, N. Tuning Film Stresses for Open-Air Processing of Stable Metal Halide Perovskites. ACS Appl Mater Interfaces 2023, 15, 51117-51125, doi: 10.1021/acsami.3c11151.
21. Rolston, N.; Bush, K. A.; Printz, A. D.; Gold-Parker, A.; Ding, Y.; Toney, M. F.; McGehee, M. D.; Dauskardt, R. H. Engineering Stress in Perovskite Solar Cells to Improve Stability. Adv Energy Mater 2018, 8, doi: 10.1002/aenm.201802139.
22. Abbas, M.; Zeng, L.; Guo, F.; Rauf, M.; Yuan, X. C.; Cai, B. A Critical Review on Crystal Growth Techniques for Scalable Deposition of Photovoltaic Perovskite Thin Films. Materials 2020, 13, 1-42.
23. Hu, H.; Singh, M.; Wan, X.; Tang, J.; Chu, C. W.; Li, G. Nucleation and Crystal Growth Control for Scalable Solution-Processed Organic-Inorganic Hybrid Perovskite Solar Cells. J Mater Chem A Mater 2020, 8, 1578-1603.
24. Zheng, D.; Raffin, F.; Volovitch, P.; Pauporte, T. Control of Perovskite Film Crystallization and Growth Direction to Target Homogeneous Monolithic Structures. Nat Commun 2022, 13, doi: 10.1038/s41467-022-34332-3.
25. Yang, Y.; Xue, Z.; Chen, L.; Lau, C. F. J.; Wang, Z. Large-Area Perovskite Films for PV Applications: A Perspective from Nucleation and Crystallization. Journal of Energy Chemistry 2021, 59, 626-641.
26. Pascoe, A. R.; Gu, Q.; Rothmann, M. U.; Li, W.; Zhang, Y.; Scully, A. D.; Lin, X.; Spiccia, L.; Bach, U.; Cheng, Y. B. Directing Nucleation and Growth Kinetics in Solution-Processed Hybrid Perovskite Thin-Films. Sci China Mater 2017, 60, 617-628, doi: 10.1007/s40843-017-9043-y.
27. Mehranpour, H.; Askari, M.; Sasani, M. Nucleation and Growth of TiO2 Nanoparticles. In Nanomaterials; InTech, 2011.
28 Rolston, N.; Scheideler, W. J.; Flick, A. C.; Chen, J. P.; Elmaraghi, H.; Sleugh, A.; Zhao, O.; Woodhouse, M.; Dauskardt, R. H. Rapid Open-Air Fabrication of Perovskite Solar Modules. Joule 2020, 4, 2675-2692, doi: 10.1016/j.joule.2020.11.001.
29. O. Fischer et al., “Understanding Contact Nonuniformities at Interfaces in Perovskite Silicon Tandem Solar Cells Using Luminescence Imaging, Lock-in Thermography, and 2D/3D Simulations,” Solar RRL, Vol. 7, No. 19, p. 2300249, 2023.;
30. O. Breitenstein, W. Warta, M. Langenkamp, and SpringerLink, Lock-in Thermography: Basics and Use for Evaluating Electronic Devices and Materials, Thrid Edition. Ed. (Springer Series in Advanced Microelectronics Volume 10). Cham, Switzerland: Springer (in English), 2018.

### Example 4

### Scalable Solar: Perovskite Thin Films Enabled by Food Industry Additive

### Background

Perovskite materials hold the potential for making high-efficiency, low-cost solar devices through solution processing of Earth abundant materials. Research utilizes spin coating as a means of reliable application, but this method lacks the scalability demanded in industry. For this reason, blade coating has been utilized as a conduit for scalable roll-to-roll fabrication of perovskite thin films; however, unmodified inks prove unsuitable for this meniscus governed process. Gellan gum, a biopolymer from the food industry, enables scalable, open-air manufacturing by altering fluid dynamics and free energy of formation to vary supersaturation rates.

Those skilled in the art will recognize, or be able to ascertain, using no more than routine experimentation, numerous equivalents to the specific substances and procedures described herein. Such equivalents are considered to be within the scope of this invention and are covered by the following claims.

### EQUIVALENTS

Those skilled in the art will recognize, or be able to ascertain, using no more than routine experimentation, numerous equivalents to the specific substances and procedures described herein. Such equivalents are considered to be within the scope of this invention and are covered by the following claims.

What is claimed is:

1. A method of producing a quench-free perovskite material in ambient conditions, the method comprising:
mixing a perovskite precursor with an organic solvent, thereby producing a perovskite precursor solution;
incorporating a polymer additive into the perovskite precursor solution, thereby producing a perovskite-polymer ink;
depositing the perovskite-polymer ink on a substrate; and
flame annealing the perovskite-polymer ink on the substrate, thereby producing a quench-free perovskite material in ambient conditions.

2. The method of claim 1, wherein the perovskite precursor comprises CH₃NH₃PbI₃.

3. The method of claim 1, wherein the polymer additive comprises gellan gum.

4. The method of claim 1, wherein the polymer additive comprises a polymer of the following structure:

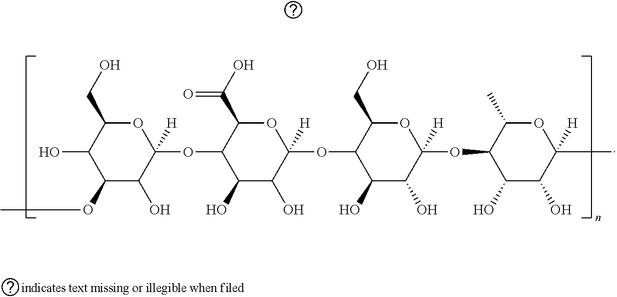

5. The method of claim 3 or claim 4, wherein the polymer additive is present in about 0.01 wt. % to about 2.29 wt. % of the perovskite precursors.

6. The method of claim 5, wherein the polymer additive is present in about 0.18 wt. % to about 0.56 wt. % of the perovskite precursors.

7. The method of claim 1, wherein the depositing comprises blade coating, bar coating, slot die coating, spray coating, inkjet printing, and gravure printing.

8. The method of claim 1, wherein the flame annealing comprises an exposure to flame discharge at speeds comprising about 0.1 m/min to about 1000 m/min.

9. The method of claim 1, wherein the flame annealing comprises flame exposure at a distance of about 0.1 cm to about 10 cm.

10. The method of claim 1, wherein the method does not require a quenching step.

11. The method of claim 1, wherein the perovskite material has improved fracture energy compared to a solution-processed material.

12. The method of claim 11, where in the fracture energy is greater than about 6.0 J/m².

13. The method of claim 11, wherein the fracture energy is about 6.6+/−2.5 J/m² to about 10.9+/−2.3 J/m².

14. The method of claim 1, further comprising tuning the morphology of the perovskite material by adjusting the concentration of the polymer additive to reduce the amount of nucleation.

15. The method of claim 14, wherein the morphology comprises domains greater than about 1 mm.

16. The method of claim 1, wherein the perovskite material has a root mean square roughness of about 1 nm to about 50 nm.

17. The method of claim 1, wherein the perovskite material has a carrier lifetime of greater than about 1 μs.

18. The method of claim 1, wherein the perovskite has increased resistance against heat and humidity.

19. A perovskite material produced by the method of claim 1.

20. The perovskite material of claim 19, wherein the material is a perovskite solar cell.
